(19) United States
(12) Patent Application Publication
(10) Pub. No.: US 2024/0381647 A1
(43) Pub. Date: Nov. 14, 2024

(54) SEMICONDUCTOR DEVICE AND METHOD OF MANUFACTURING THE SAME

(71) Applicant: Kioxia Corporation, Tokyo (JP)

(72) Inventors: Tatsunori ISOGAI, Yokkaichi (JP); Shunsuke OKADA, Suzuka (JP); Tomonori AOYAMA, Yokkaichi (JP); Masaki NOGUCHI, Yokkaichi (JP)

(73) Assignee: Kioxia Corporation, Tokyo (JP)

(21) Appl. No.: 18/781,400

(22) Filed: Jul. 23, 2024

Related U.S. Application Data
(62) Division of application No. 17/202,581, filed on Mar. 16, 2021.

(30) Foreign Application Priority Data
Jul. 7, 2020 (JP) 2020-117284

(51) Int. Cl. H10B 43/27; H01L 21/223; H01L 21/225; H01L 23/00; H01L 25/00; H01L 25/18

(52) U.S. Cl. CPC H10B 43/27; H01L 21/223; H01L 21/2253; H01L 24/08; H01L 24/32; H01L 24/80; H01L 24/83; H01L 24/92; H01L 25/18; H01L 25/50; H01L 2224/08145; H01L 2224/32145; H01L 2224/80895; H01L 2224/83896; H01L 2224/92142; H01L 2924/1431; H01L 2924/14511

(57) ABSTRACT

In one embodiment, a semiconductor device includes a stacked film including a plurality of electrode layers and a plurality of insulating layers alternately stacked in a first direction. The device further includes a columnar portion including a charge storage layer and a first semiconductor layer extending through the stacked film in the first direction, the first semiconductor layer including an impurity element. The device further includes a second semiconductor layer or a first insulator provided on the stacked film and the columnar portion, the second semiconductor layer or the first insulator including the impurity element and having a concentration gradient of the impurity element in the first direction.

### CROSS REFERENCE TO RELATED APPLICATION

This application is a division of and claims benefit under 35 U.S.C. § 120 to U.S. patent application Ser. No. 17/202,581, filed Mar. 16, 2021, which is based upon and claims the benefit of priority under 35 U.S.C. § 119 from Japanese Patent Application No. 2020-117284, filed on Jul. 7, 2020, the entire contents of each of which are incorporated herein by reference.

### FIELD

Embodiments described herein relate to a semiconductor device and a method of manufacturing the same.

### BACKGROUND

When a semiconductor device includes impurity atoms, it is preferable to optimize influences of the impurity atoms on performance of the semiconductor device.

### BRIEF DESCRIPTION OF THE DRAWINGS

FIG. 1 is a cross-sectional view showing a structure of a semiconductor device of a first embodiment;

FIG. 2 is an enlarged cross-sectional view showing the structure of the semiconductor device of the first embodiment;

FIGS. 3A to 7B illustrate cross-sectional views showing a method of manufacturing the semiconductor device of the first embodiment;

FIGS. 8A to 8C illustrate cross-sectional views showing details of the method of manufacturing the semiconductor device of the first embodiment;

FIGS. 9A and 9B illustrate graphs each describing a concentration of phosphorus atoms in the semiconductor device of the first embodiment;

FIGS. 10A and 10B illustrate cross-sectional views showing a method of manufacturing a semiconductor device of a modification of the first embodiment;

FIG. 11 is a cross-sectional view showing a structure of a semiconductor device of a second embodiment;

FIG. 12 is an enlarged cross-sectional view showing the structure of the semiconductor device of the second embodiment;

FIGS. 13A to 21B illustrate cross-sectional views showing a method of manufacturing the semiconductor device of the second embodiment;

FIG. 22 is a graph describing a concentration of phosphorus atoms included in a semiconductor layer or the like of the second embodiment;

FIG. 23 is a cross-sectional view showing a structure of a semiconductor device of a third embodiment;

FIGS. 24A and 24B illustrate cross-sectional views showing a method of manufacturing the semiconductor device of the third embodiment; and

FIG. 25 is a cross-sectional view showing an overall structure of the semiconductor device of the first embodiment.

### DETAILED DESCRIPTION

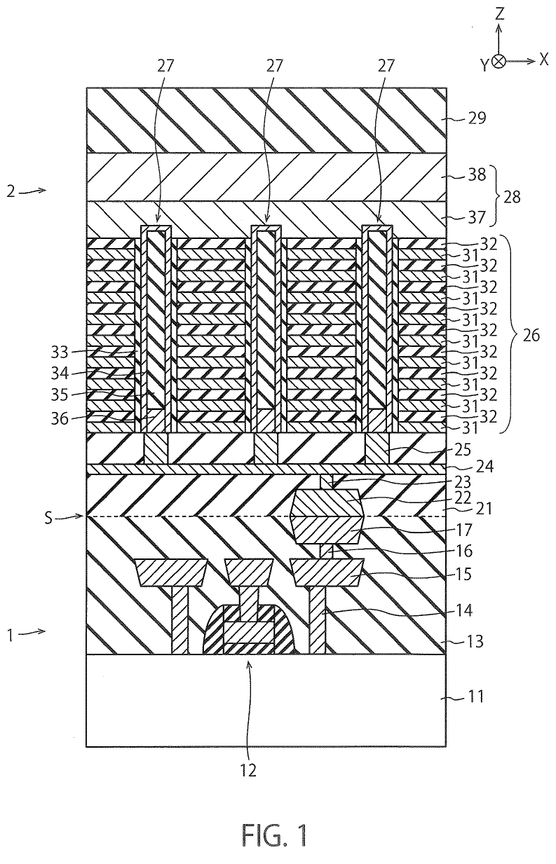

Embodiments will now be explained with reference to the accompanying drawings. In FIGS. 1 to 25, the same components are assigned the same reference numerals and duplicate description will be skipped.

In one embodiment, a semiconductor device includes a stacked film including a plurality of electrode layers and a plurality of insulating layers alternately stacked in a first direction. The device further includes a columnar portion including a charge storage layer and a first semiconductor layer extending through the stacked film in the first direction, the first semiconductor layer including an impurity element. The device further includes a second semiconductor layer or a first insulator provided on the stacked film and the columnar portion, the second semiconductor layer or the first insulator including the impurity element and having a concentration gradient of the impurity element in the first direction.

### First Embodiment

FIG. 1 is a cross-sectional view showing a structure of a semiconductor device of a first embodiment. The semiconductor device in FIG. 1 is, for example, a three-dimensional flash memory.

The semiconductor device in FIG. 1 includes a circuit region 1 including a CMOS (complementary metal oxide semiconductor) circuit and an array region 2 including a memory cell array. The memory cell array includes a plurality of memory cells that store data and the CMOS circuit includes a peripheral circuit that controls operation of the memory cell array. The semiconductor device in FIG. 1 is manufactured by bonding a circuit wafer including the circuit region 1 and an array wafer including the array region 2 as will be described later. Reference character S denotes a bonded surface of the circuit region 1 and the array region 2.

FIG. 1 illustrates an X direction, a Y direction and a Z direction that are perpendicular to each other. In the present specification, a +Z direction is handled as an upward direction and a −Z direction is handled as a downward direction. For example, the CMOS region 1 is shown in the −Z direction of the array region 2, and so the CMOS region 1 is located below the array region 2. The −Z direction may coincide with the direction of gravity or may not coincide with the direction of gravity. The Z direction is an example of a first direction.

In FIG. 1, the circuit region 1 includes a substrate 11, a transistor 12, an inter layer dielectric 13, a plurality of contact plugs 14, an interconnect layer 15 including a plurality of interconnects, a via plug 16 and a metal pad 17. FIG. 1 illustrates three of the plurality of interconnects in the interconnect layer 15 and three contact plugs 14 provided below the interconnects. The substrate 11 is an example of a first substrate. The metal pad 17 is an example of a first pad.

In FIG. 1, the array region 2 includes an inter layer dielectric 21, a metal pad 22, a via plug 23, an interconnect layer 24 including a plurality of interconnects, a plurality of contact plugs 25, a stacked film 26, a plurality of columnar portions 27, a source layer 28 and an insulator 29. FIG. 1 illustrates one of the plurality of interconnects in the interconnect layer 24, three contact plugs 25 and three columnar portions 27 provided on this interconnect. The metal pad 22 is an example of a second pad.

Furthermore, the stacked film 26 includes a plurality of electrode layers 31 and a plurality of insulating layers 32. Each columnar portion 27 includes a memory insulator 33, a channel semiconductor layer 34, a core insulator 35 and a core semiconductor layer 36. The source layer 28 includes a semiconductor layer 37 and a metal layer 38. The channel semiconductor layer 34 is an example of a first semiconductor layer. The semiconductor layer 37 is an example of a second semiconductor layer.

Hereinafter, a structure of the semiconductor device of the present embodiment will be described with reference to FIG. 1.

The substrate 11 is a semiconductor substrate such as a Si (silicon) substrate. The transistor 12 is provided on the substrate 11 and includes a gate insulator and a gate electrode. The transistor 12 constitutes, for example, the aforementioned CMOS circuit. The inter layer dielectric 13 is formed so as to cover the transistor 12 on the substrate 11. The inter layer dielectric 13 is a stacked film including, for example, a SiO₂ film (silicon oxide film) or a SiO₂ film and other insulators.

The contact plugs 14, the interconnect layer 15, the via plug 16 and the metal pad 17 are formed in the inter layer dielectric 13. More specifically, the contact plug 14 is disposed on the substrate 11 or on the gate electrode of the transistor 12. In FIG. 1, the contact plug 14 on the substrate 11 is provided in a source region and a drain region (not illustrated) of the transistor 12. The interconnect layer 15 is disposed on the contact plug 14. The via plug 16 is disposed on the interconnect layer 15. The metal pad 17 is disposed on the via plug 16 above the substrate 11. The metal pad 17 is, for example, a Cu (copper) layer.

The inter layer dielectric 21 is formed on the inter layer dielectric 13. The inter layer dielectric 21 is a stacked film including, for example, a SiO₂ film or SiO₂ film and other insulators.

The metal pad 22, the via plug 23, the interconnect layer 24 and the contact plugs 25 are formed in the inter layer dielectric 21. More specifically, the metal pad 22 is disposed on the metal pad 17 above the substrate 11. The metal pad 22 is, for example, a Cu layer. The via plug 23 is disposed on the metal pad 22. The interconnect layer 24 is disposed on the via plug 23. FIG. 1 illustrates one of the plurality of interconnects in the interconnect 10 layer 24 and this interconnect functions, for example, as a bit line. The contact plugs 25 are disposed on the interconnect layer 24.

The stacked film 26 is provided on the inter layer dielectric 21 and includes a plurality of electrode layers 31 and a plurality of insulating layers 32, which are alternately stacked in the Z direction. The electrode layer 31 is a metal layer including, for example, a W (tungsten) layer and functions as a word line. The insulating layer 32 is, for example, a SiO₂ film. In the present embodiment, the above plurality of electrode layers 31 have the same thickness and the above plurality of insulating layers 32 also have the same thickness. However, as will be described later, the thickness of the most upper insulating layer 32 among the insulating layers 32 may be larger than the thickness of other insulating layers 32.

Each columnar portion 27 is provided in the stacked film 26 and includes the memory insulator 33, the channel semiconductor layer 34, the core insulator 35 and the core semiconductor layer 36. The memory insulator 33 is formed on a side surface of the stacked film 26 and has a tubular shape extending in the Z direction. The channel semiconductor layer 34 is formed on a side surface of the memory insulator 33 and has a tubular shape extending in the Z direction. The core insulator 35 and the core semiconductor layer 36 are formed on a side surface of the channel semiconductor layer 34 and have a bar-like shape extending in the Z direction. More specifically, the core semiconductor layer 36 is disposed on the contact plugs 25 and the core insulator 35 is disposed on the core semiconductor layer 36.

As will be described later, the memory insulator 33 includes, for example, a block insulator, a charge storage layer and a tunnel insulator in order. The block insulator is, for example, a SiO₂ film. The charge storage layer is, for example, a SiN film (silicon nitride film). The tunnel insulator is for example, a SiO₂ film or SiON film (silicon oxynitride film). The channel semiconductor layer 34 is, for example, a polysilicon layer. The core insulator 35 is, for example, a SiO₂ film. The core semiconductor layer 36 is, for example, a polysilicon layer. Each memory cell in the aforementioned memory cell array is constructed of the channel semiconductor layer 34, the charge storage layer, the electrode layer 31 or the like.

The channel semiconductor layer 34 in each columnar portion 27 is provided at a position higher than the metal pad 22, but is electrically connected to the metal pad 22 via the core semiconductor layer 36, the contact plugs 25, the interconnect layer 24 and the via plug 23. Therefore, the memory cell array in the array region 2 is electrically connected to a peripheral circuit in the circuit region 1 via the metal pad 22 and the metal pad 17. This makes it possible for the peripheral circuit to control operation of the memory cell array.

The source layer 28 includes a semiconductor layer 37 and a metal layer 38 formed in order on the stacked film 26 and the columnar portion 27, and functions as a source line. In the present embodiment, the channel semiconductor layer 34 of each columnar portion 27 is exposed from the memory insulator 33 and the semiconductor layer 37 is directly formed on the channel semiconductor layer 34. Furthermore, the metal layer 38 is directly formed on the semiconductor layer 37. Therefore, the source layer 28 is electrically connected to the channel semiconductor layer 34 of each columnar portion 27. The semiconductor layer 37 is, for example, a polysilicon layer. The metal layer 38 includes, for example, a W layer, a Cu layer or an Al (aluminum) layer.

The insulator 29 is formed on the source layer 28. The insulator 29 is, for example, a SiO₂ film.

Here, impurity atoms included in the semiconductor device of the present embodiment will be described.

The semiconductor layer 37 of the present embodiment includes predetermined impurity atoms. These impurity atoms are, for example, P (phosphorus) atoms. In the present embodiment, the impurity atoms are also included in the channel semiconductor layer 34 and at least the most upper insulating layer 32 among the aforementioned plurality of insulating layers 32. The reason why the semiconductor layer 37, the channel semiconductor layer 34 and this insulating layer 32 of the present embodiment include the same impurity atoms will be described later.

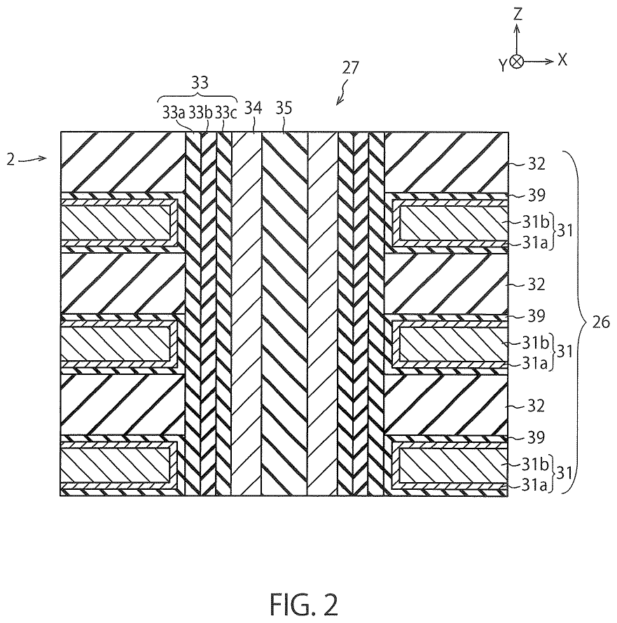

FIG. 2 is an enlarged cross-sectional view showing a structure of the semiconductor device of the first embodiment.

FIG. 2 illustrates three electrode layers 31 and three insulating layers 32 included in the stacked film 26 and one columnar portion 27 provided in the stacked film 26. As described above, the memory insulator 33 in the columnar portion 27 includes a block insulator 33a, a charge storage layer 33b and a tunnel insulator 33c formed in order on a side surface of the stacked film 26. The block insulator 33a is, for example, a SiO₂ film. The charge storage layer 33b is, for example, a SiN film. The tunnel insulator 33c is, for example, a SiO₂ film or SiON film.

On the other hand, each electrode layer 31 includes a barrier metal layer 31a and an electrode member layer 31b. The barrier metal layer 31a is, for example, a TiN film (titanium nitride film). The electrode member layer 31b is, for example, a W layer. Each electrode layer 31 of the present embodiment is formed on an undersurface of the insulating layer 32 above, a top surface of the insulating layer 32 below and a side surface of the block insulator 33a via a block insulator 39 as illustrated in FIG. 2. The block insulator 39 is, for example, an Al₂O₃ film (aluminum oxide film) and functions as a block insulator of each memory cell together with the block insulator 33a. In this way, the stacked film 26 of the present embodiment includes the block insulator 39 in addition to the electrode layer 31 and the insulating layer 32. The block insulator 39, the barrier metal layer 31a and the electrode member layer 31b are formed in order on the undersurface of the insulating layer 32 above, the top surface of the insulating layer 32 below and the side surface of the block insulator 33a.

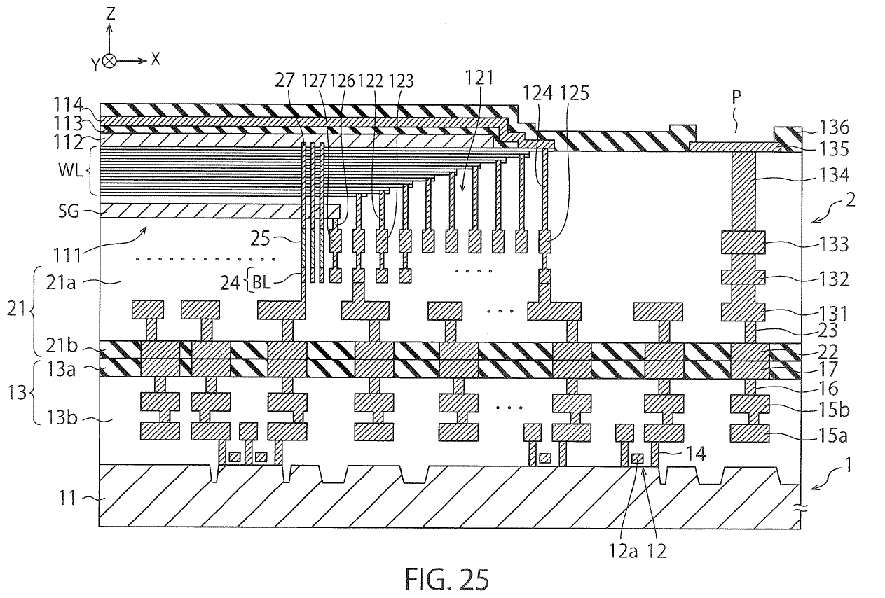

FIG. 25 is a cross-sectional view showing an overall structure of the semiconductor device of the first embodiment.

The array region 2 includes a memory cell array 111 including a plurality of memory cells, a semiconductor layer 112 on the memory cell array 111, a back-gate insulator 113 on the semiconductor layer 112, and a back-gate electrode 114 on the back-gate insulator 113. The back-gate electrode 114 is used for controlling electric fields of the semiconductor layer 112 like a selection gate SG to be descried later. The array region 2 further includes, as the inter layer dielectric 21, an inter layer dielectric 21a under the memory cell array 111 and an insulator 21b under the inter layer dielectric 21a. The insulator 21b is a silicon oxide film, for example.

The circuit region 1 is provided under the array region 2. The circuit region 1 includes, as the inter layer dielectric 13, an insulator 13a under the insulator 21b, an inter layer dielectric 13b under the insulator 13a, and the substrate 11 under the inter layer dielectric 13b. The insulator 13a is a silicon oxide film, for example. The substrate 11 is a semiconductor substrate such as a silicon substrate, for example.

The array region 2 includes a plurality of word lines WL and a selection gate SG as electrode layers in the memory cell array 111. FIG. 25 illustrates a step-like structure portion 121 of the memory cell array 111. The array region 2 further includes the above-described back-gate electrode 114 as an electrode layer outside the memory cell array 111. As illustrated in FIG. 25, each of the word lines WL is electrically connected to a word interconnect layer 123 via a contact plug 122, the back-gate electrode 114 is electrically connected to a back-gate interconnect layer 125 via a contact plug 124, and the selection gate SG is electrically connected to a selection gate interconnect layer 127 via a contact plug 126. A columnar portion 27 piercing through the word lines WL and the selection gate SG is electrically connected to a bit line BL in the interconnect layer 24 via the contact plug 25 and electrically connected to the semiconductor layer 112 as well. The word lines WL are examples of the electrode layers 31 described above.

The circuit region 1 includes a plurality of transistors 12. Each of the transistors 12 includes a gate electrode 12a provided on the substrate 11 via a gate insulator, and a source diffusion layer as well as a drain diffusion layer, not shown, provided in the substrate 11. The circuit region 1 further includes a plurality of contact plugs 14 provided on the source diffusion layer or the drain diffusion layer of those transistors 12, an interconnect layer 15a including a plurality of interconnects provided on those contact plugs 14, and an interconnect layer 15b including a plurality of interconnects provided on the interconnect layer 15a. The circuit region 1 further includes a plurality of via plugs 16 provided on the interconnect layer 15b, and a plurality of metal pads 17 provided on the via plugs 16 in the insulator 13a. The circuit region 1 functions as a control circuit (logic circuit) that controls the array region 2. The interconnect layers 15a and 15b are examples of the interconnect layer 15 described above.

The array region 2 includes a plurality of metal pads 22 provided on the metal pads 17 in the insulator 21b, a plurality of via plugs 23 provided on the metal pads 22, and an interconnect layer 131 including a plurality of interconnects provided on those via plugs 23. Each of the word lines WL and each of the bit lines BL are electrically connected to the corresponding lines in the interconnect layer 131. The array region 2 further includes an interconnect layer 132 including a plurality of interconnects provided on the interconnect layer 131, an interconnect layer 133 including a plurality of interconnects provided on the interconnect layer 132, and a via plug 134 provided on the interconnect layer 133. The array region 2 further includes a metal pad 135 provided on the via plug 134, and a passivation film 136 that covers the metal pad 135 and the back-gate electrode 114. The passivation film 136 is a silicon oxide film, for example, and includes an opening portion P for exposing the upper face of the metal pad 135. The metal pad 135 is an external connection pad of the semiconductor device illustrated in FIG. 25, and can be connected to a mounting board or another device via solder balls, metal bumps, wire bonding, or the like.

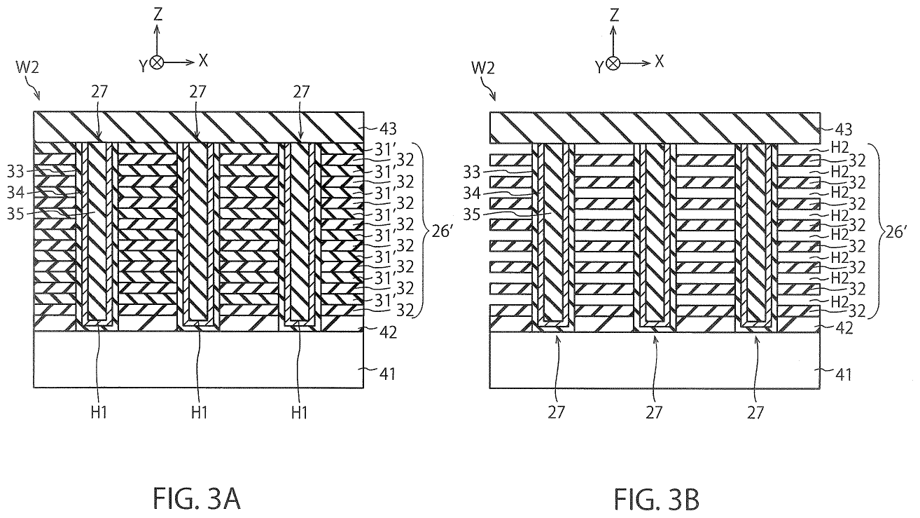

FIGS. 3A to 7B illustrate cross-sectional views showing a method of manufacturing the semiconductor device of the first embodiment.

FIG. 3A illustrates an array wafer W2 for manufacturing the array region 2. In order to manufacture the array region 2, an insulator 42 is formed on the substrate 41 first and a plurality of sacrificial layers 31′ and a plurality of insulating layers 32 are alternately formed on the insulator 42 (FIG. 3A). As a result, a stacked film 26′ is formed on the insulator 42. The stacked film 26′ includes a plurality of sacrificial layers 31′ and a plurality of insulating layers 32 alternately stacked in the Z direction. The substrate 41 is, for example, a semiconductor substrate such as a Si substrate. The substrate 41 is an example of a second substrate. The insulator 42 is, for example, a SIN film. The sacrificial layer 31′ is, for example, SiN.

Next, a plurality of memory holes H1 that penetrate the stacked film 26′ and the insulator 42 are formed and the memory insulator 33, the channel semiconductor layer 34 and the core insulator 35 are formed in order in each memory hole H1 (FIG. 3A). As a result, the plurality of columnar portions 27 extending in the Z direction are formed in the memory holes H1. The memory insulator 33 is formed by forming the block insulator 33a, the charge storage layer 33b and the tunnel insulator 33c in order in each memory hole H1 (see FIG. 2).

Next, an insulator 43 is formed on the stacked film 26′ and the columnar portions 27 (FIG. 3A). The insulator 43 is, for example, a SiO₂ film.

Next, a slit (not illustrated) that penetrates the insulator 43 and the stacked film 26′ is formed and the sacrificial layers 31′ are removed by wet etching using the slit (FIG. 3B). As a result, a plurality of cavities H2 are formed between the insulating layers 32 in the stacked film 26′.

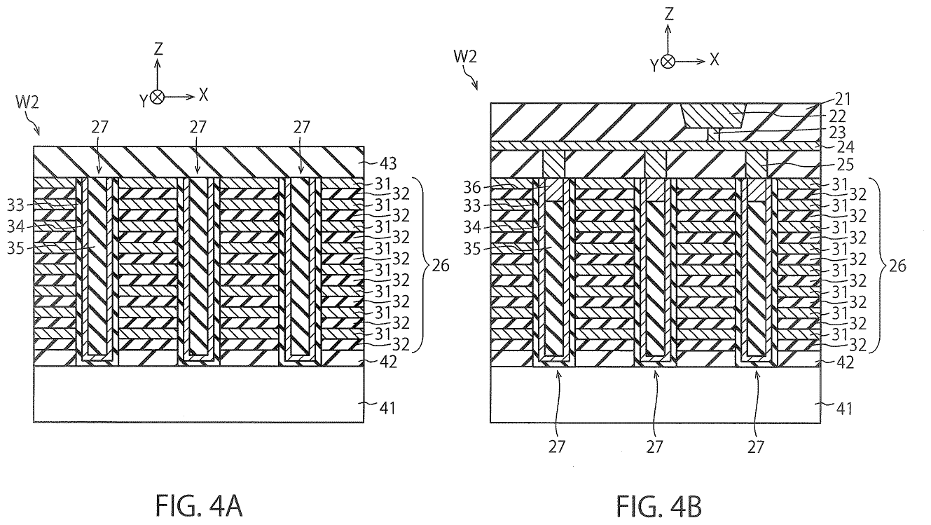

Next, a plurality of electrode layers 31 are formed in the cavities H2 from the slit (FIG. 4A). As a result, a stacked film 26 including the plurality of electrode layers 31 and the plurality of insulating layers 32 alternately stacked in the Z direction is formed between the insulator 42 and the insulator 43. Furthermore, a structure in which the above-described plurality of columnar portions 27 penetrate the stacked film 26 is formed above the substrate 41. When the electrode layer 31 is formed in each cavity H2, the block insulator 39, the barrier metal layer 31a and the electrode member layer 31b are formed in order in each cavity H2 (see FIG. 2).

Next, the insulator 43 is removed, a portion of the core insulator 35 in each columnar portion 27 is removed, and the core semiconductor layer 36 is embedded in the region from which a portion of the core insulator 35 has been removed (FIG. 4B). As a result, each columnar portion 27 is processed into a structure including the memory insulator 33, the channel semiconductor layer 34, the core insulator 35 and the core semiconductor layer 36.

Next, the inter layer dielectric 21, the metal pad 22, the via plug 23, the interconnect layer 24 and the plurality of contact plugs 25 are formed on the stacked film 26 and the columnar portion 27 (FIG. 4B). In this case, these contact plugs 25 are formed on the core semiconductor layers 36 of the corresponding columnar portions 27, and the interconnect layer 24, the via plug 23 and the metal pad 22 are formed in order on these contact plugs 25.

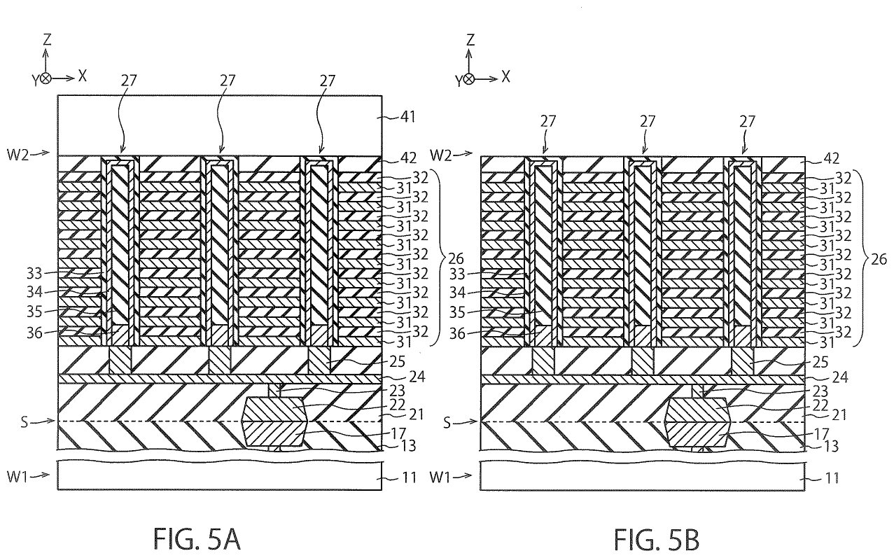

FIG. 5A illustrates a circuit wafer W1 for manufacturing the circuit region 1. The circuit wafer W1 in FIG. 5A is manufactured by forming the transistor 12, the inter layer dielectric 13, the plurality of contact plugs 14, the interconnect layer 15, the via plug 16 and the metal pad 17 on the substrate 11 (see FIG. 1). In this case, the transistor 12 is formed on the substrate 11 and these contact plugs 14 are formed on the substrate 11 and the transistor 12. Furthermore, the interconnect layer 15, the via plug 16 and the metal pad 17 are formed in order on the contact plugs 14. The substrate 11 is an example of a first substrate.

Next, the orientation of the array wafer W2 is inverted, and the circuit wafer W1 and the array wafer W2 are bonded under a mechanical pressure (FIG. 5A). As a result, the inter layer dielectric 13 and the inter layer dielectric 21 are bonded. Next, the circuit wafer W1 and the array wafer W2 are annealed (FIG. 5A). As a result, the metal pad 17 and the metal pad 22 are joined. In this way, the metal pad 22 on the substrate 41 is bonded to the metal pad 17 on the substrate 11, the inter layer dielectric 21 on the substrate 41 is bonded to the inter layer dielectric 13 on the substrate 11 and the substrate 41 is stacked above the substrate 11.

Next, the substrate 41 is removed (FIG. 5B). As a result, the insulator 42 and each columnar portion 27 are exposed above the substrate 11. The substrate 41 is removed, for example, by CMP (chemical mechanical polishing). In the step in FIG. 5B, not only the substrate 41 is removed by CMP but the substrate 11 may be thinned by CMP.

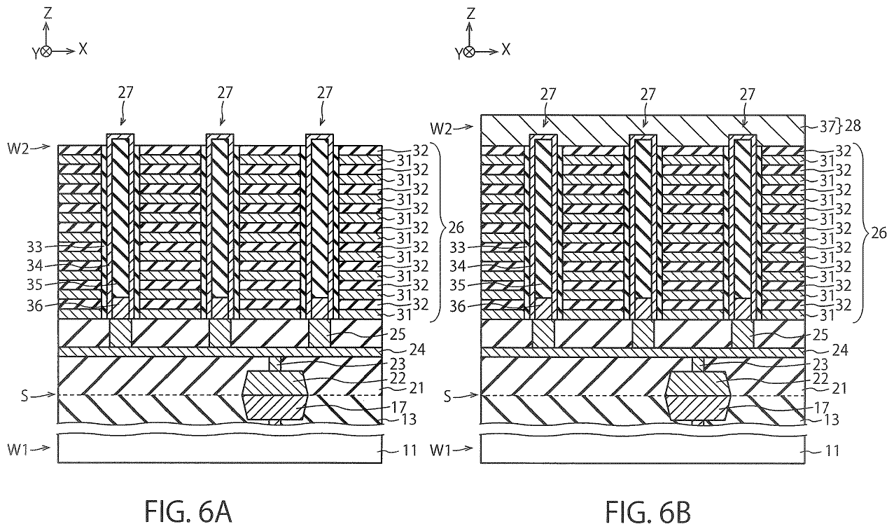

Next, the insulator 42 and a portion of the memory insulator 33 of each columnar portion 27 are removed by etching (FIG. 6A). The portion of the memory insulator 33 to be removed is, for example, a portion exposed from the stacked film 26. As a result, a portion of the channel semiconductor layer 34 of each columnar portion 27 is exposed from the memory insulator 33 at a position higher than the stacked film 26.

Next, a semiconductor layer 37 of the source layer 28 is formed on the stacked film 26 and the columnar portion 27 (FIG. 6B). As a result, the semiconductor layer 37 is formed on the channel semiconductor layer 34 of each columnar portion 27, and so the semiconductor layer 37 is electrically connected to the channel semiconductor layer 34 of each columnar portion 27.

In the step in FIG. 6B, the semiconductor layer 37 is formed as an amorphous semiconductor layer. This amorphous semiconductor layer is, for example, an a-Si (amorphous silicon) layer. In the present embodiment, the semiconductor layer 37 as the a-Si layer is formed using a source gas including, for example, elements of Si (silicon) and H (hydrogen). Therefore, the semiconductor layer 37 formed in the step in FIG. 6B includes H atoms as impurity atoms. The H atoms are preferably desorbed from the semiconductor layer 37.

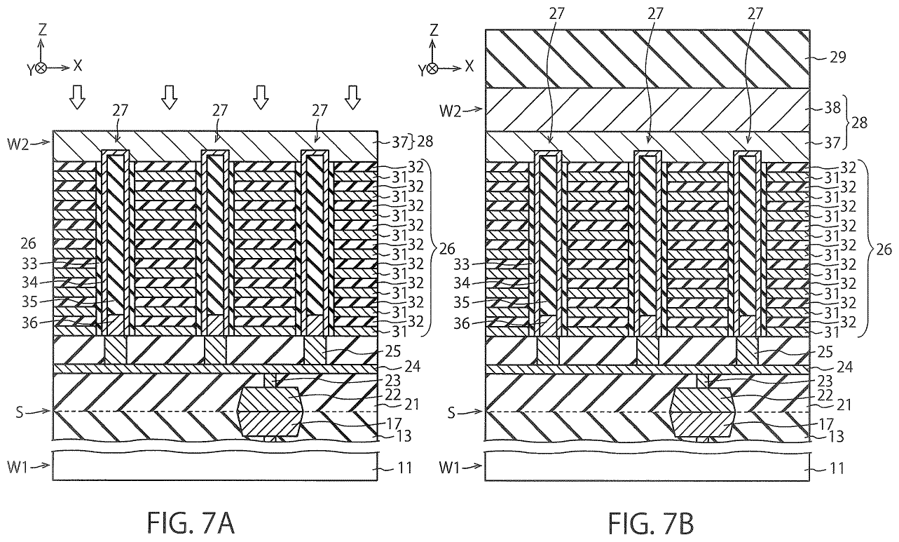

Next, ion implantation into the semiconductor layer 37 is performed using P (phosphorus) ions (FIG. 7A). As a result, P atoms as impurity atoms are introduced into the semiconductor layer 37. As will be described later, the P atoms have an effect of promoting desorption of H atoms from the semiconductor layer 37.

Next, the semiconductor layer 37 is annealed to desorb H atoms from the semiconductor layer 37 (FIG. 7A). As a result, at least some H atoms in the semiconductor layer 37 are desorbed from the semiconductor layer 37 and the concentration of H atoms in the semiconductor layer 37 decreases. The annealing in the step in FIG. 7A is an example of first annealing.

In this way, in the present embodiment, in order to desorb H atoms, impurity atoms, from the semiconductor layer 37, P atoms, different impurity atoms, are introduced into the semiconductor layer 37. In the present embodiment, the P atoms remain in the final semiconductor layer 37, that is, the semiconductor layer 37 of the manufactured (finished) semiconductor device. In the above-described ion implantation, there is a possibility that P ions may also be implanted into the channel semiconductor layer 34 of each columnar portion 27 and at least the most upper insulating layer 32 among the plurality of insulating layers 32. In this case, P atoms also eventually remain in the channel semiconductor layer 34 or in the insulating layer 32. P atoms may also be introduced and eventually remain in the other insulating layers 32 of the stacked film 26. Further details of the step in FIG. 7A will be described later.

Next, the semiconductor layer 37 is annealed by laser annealing (FIG. 7B). As a result, the semiconductor layer 37 is crystallized and changed from the amorphous semiconductor layer to a polycrystal semiconductor layer. The crystallized semiconductor layer 37 is, for example, a polysilicon layer. The annealing in the step in FIG. 7B is an example of second annealing.

Next, the metal layer 38 of the source layer 28 is formed on the semiconductor layer 37 and the insulator 29 is formed on the metal layer 38 (FIG. 7B).

After that, the circuit wafer W1 and the array wafer W2 are cut into a plurality of chips. These chips are cut so that each chip includes the circuit region 1 and the array region 2. In this way, the semiconductor device in FIG. 1 is manufactured.

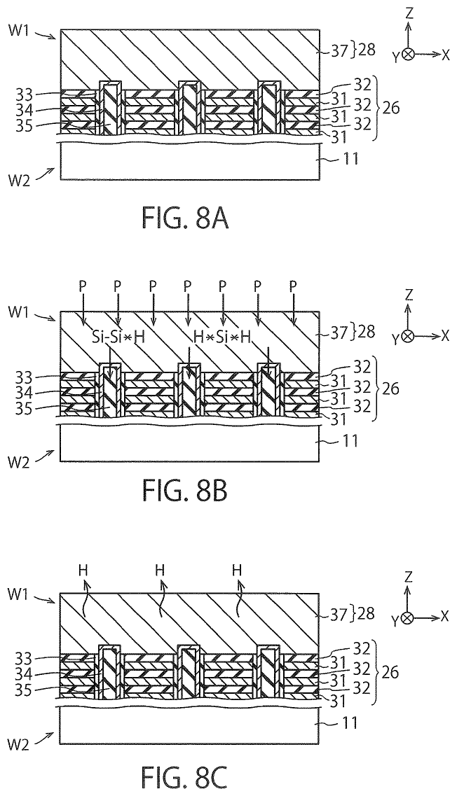

FIGS. 8A to 8C illustrate cross-sectional views showing details of the method of manufacturing the semiconductor device of the first embodiment. FIGS. 8A to 8C illustrate details of the step in FIG. 7A.

FIG. 8A illustrates the semiconductor layer 37 before performing ion implantation. Therefore, the semiconductor layer 37 in FIG. 8A is an a-Si layer including H atoms as impurity atoms.

FIG. 8B illustrates ion implantation into the semiconductor layer 37. P atoms as impurity atoms are introduced into the semiconductor layer 37 in the step in FIG. 8B. FIG. 8B further schematically illustrates Si atoms and H atoms included in the semiconductor layer 37. The Si atoms and H atoms form Si—Si bonds and Si—H bonds. According to the present embodiment, introducing P atoms into the semiconductor layer 37 makes it possible for P atoms to disconnect Si—H bonds. This can promote desorption of H atoms from the semiconductor layer 37.

From the standpoint of cutting Si—H bonds, impurity atoms to be introduced into the semiconductor layer 37 may be impurity atoms other than P atoms that can cut Si—H bonds. However, introducing P atoms into the semiconductor layer 37 makes it possible to convert the semiconductor layer 37 to an n-type semiconductor layer to thereby improve the performance of the semiconductor layer 37. Therefore, the impurity atoms to be introduced into the semiconductor layer 37 are preferably P atoms.

The P atoms of the present embodiment are also introduced into the channel semiconductor layer 34 of each columnar portion 27 and the most upper insulating layer 32. According to the present embodiment, introducing the P atoms into the channel semiconductor layer 34 makes it possible to convert the channel semiconductor layer 34 to an n-type semiconductor layer and improve the performance of the channel semiconductor layer 34.

In the present embodiment, the concentration of P atoms in the channel semiconductor layer 34 decreases in accordance with the depth from the upper end of the channel semiconductor layer 34. The upper end of the channel semiconductor layer 34 is a distal end of the channel semiconductor layer 34 in the +Z direction and is located in the semiconductor layer 37 in FIG. 8B. Ion implantation in the present embodiment is preferably performed under a condition under which the concentration of P atoms in the channel semiconductor layer 34 becomes 1×10¹⁹ cm⁻³ or more at a position where the depth from the upper end of the channel semiconductor layer 34 is 200 nm. In this case, the concentration of P atoms in the channel semiconductor layer 34 becomes 1×10¹⁹ cm⁻³ or more in all regions between an upper end point and a point where the depth from the upper end is 200 nm. Such a condition can be set by adjusting an acceleration voltage of ion implantation and a dose amount.

According to the present embodiment, it is possible to set the concentration of P atoms in the channel semiconductor layer 34 to a high concentration near the upper end and thereby improve the performance of the channel semiconductor layer 34. For example, setting the concentration of P atoms in the channel semiconductor layer 34 to a high concentration near the upper end makes it possible to generate a sufficient GIDL (gate induced drain leakage) current, which is an erasing current of the memory cell.

The P atoms included in the semiconductor layer 37 can spread by annealing conducted after the step in FIG. 8B. Therefore, in the present embodiment, the P atoms may be made to spread over the channel semiconductor layer 34 from the semiconductor layer 37 by such annealing. Therefore, the P atoms in the channel semiconductor layer 34 of the finished semiconductor device may derive from P ions implanted into the channel semiconductor layer 34 at the time of ion implantation or may derive from the spread P atoms by annealing thereafter. The same applies to P atoms in the most upper insulating layer 32. However, since ion implantation can more easily control the concentration of P atoms than diffusion, if the concentration of P atoms in the channel semiconductor layer 34 is to be controlled to a desired concentration, it is preferable to adjust the concentration of P atoms in the channel semiconductor layer 34 by ion implantation.

The P atoms included in the channel semiconductor layer 34 can also be made to spread by annealing conducted after the step in FIG. 8B. In this case, it is preferable that the above-described concentration of 1×10¹⁹ cm⁻³ or more hold even in the channel semiconductor layer 34 of the finished semiconductor device. That is, in the finished semiconductor device, the concentration of the P atoms in the channel semiconductor layer 34 is preferably 1×10¹⁹ cm⁻³ or more at a position where the depth from the upper end of the channel semiconductor layer 34 is 200 nm. Such a concentration can be achieved by adjusting, for example, the concentration of P atoms in the channel semiconductor layer 34 at the time of ion implantation with subsequent diffusion taken into consideration.

FIG. 8C illustrates annealing (hydrogen-free annealing) of the semiconductor layer 37. In the step in FIG. 8C, H atoms are desorbed from the semiconductor layer 37 and the concentration of H atoms in the semiconductor layer 37 is reduced. In this case, H atoms cut from Si atoms are more easily desorbed from the semiconductor layer 37.

Hydrogen-free annealing is performed, for example, at a temperature less than 400° C. such that the concentration of H atoms in the semiconductor layer 37 falls to or below 10% (preferably 5% or below). The hydrogen-free annealing may be performed using an annealing furnace or may be performed by laser annealing at such low intensity that the semiconductor layer 37 is not melted. On the other hand, the laser annealing in the step in FIG. 7B may be performed at such high intensity that part or whole of the semiconductor layer 37 is melted and this causes the semiconductor layer 37 to change from an a-Si layer to a polysilicon layer.

If high-concentration H atoms remain in the semiconductor layer 37, H atoms may form H2 molecules in the semiconductor layer 37 causing voids or ablation at the time of laser annealing in the semiconductor layer 37. On the other hand, H atoms in the semiconductor layer 37 can also be desorbed from the semiconductor layer 37 by annealing at a high temperature of 400° C. or higher. However, annealing at such a high temperature may adversely affect the metal pads 17 and 22, which are Cu layers.

In the present embodiment, P atoms are introduced into the semiconductor layer 37 and H atoms are desorbed from the semiconductor layer 37 by subsequent annealing. Therefore, according to the present embodiment, it is possible to desorb H atoms from the semiconductor layer 37 by annealing at low temperature of less than 400° C. This makes it possible to suppress voids in the semiconductor layer 37 or ablation at the time of laser annealing while suppressing adverse influences on the metal pads 17 and 22.

In the present embodiment, P atoms are used as impurity atoms to promote desorption of H atoms. The P atoms also have an effect of improving the performance of the semiconductor layer 37 or the channel semiconductor layer 34. Therefore, according to the present embodiment, it is possible to simultaneously achieve two objects: promotion of desorption and improvement of performance by ion implantation. Therefore, ion implantation to improve the performance of the semiconductor layer 37 or the channel semiconductor layer 34 need not be performed apart from ion implantation to promote desorption of H atoms. This makes it possible to shorten a time necessary to manufacture the semiconductor device.

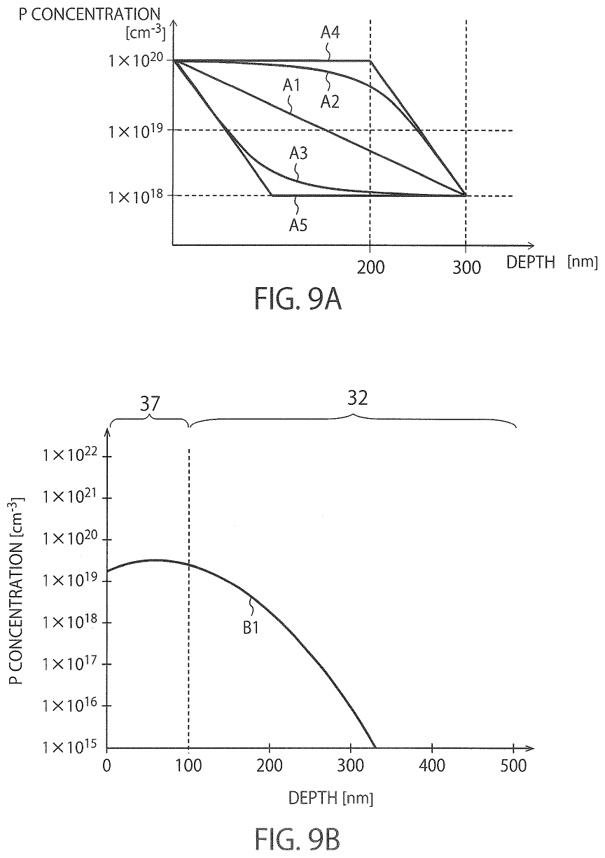

FIGS. 9A and 9B illustrate graphs each describing a concentration of P (phosphorus) atoms in the semiconductor device of the first embodiment.

A vertical axis in FIG. 9A represents a concentration of P atoms at each point in the channel semiconductor layer 34 in FIG. 1. A horizontal axis in FIG. 9A represents a depth from the upper end of the channel semiconductor layer 34 at each point in the channel semiconductor layer 34 in FIG. 1. This depth direction is parallel to the Z direction. Hereinafter, the concentration of P atoms will also be described as “P concentration.”

Curves A1 to A5 in FIG. 9A show five examples of a P concentration profile in the channel semiconductor layer 34. The P concentration profile in the channel semiconductor layer 34 may be set to any shape, and can be set to a shape of any one of the curves A1 to A5.

The curve A1 is an inclined straight line where the P concentration decreases linearly. The curve A2 is an upwardly convex curve where the P concentration decreases non-linearly. The curve A3 is a downwardly convex curve where the P concentration decreases non-linearly. The curve A4 includes a horizontal rectilinear portion and an inclined rectilinear portion in order where the P concentration is kept constant, and then decreases from a predetermined depth. The curve A5 includes an inclined rectilinear portion and a horizontal rectilinear portion in order where the P concentration decreases to a predetermined depth and is then kept constant. The curves A1 to A5 are decreasing functions in which the P concentration decreases with depth. Furthermore, the curves A1 to A3 are monotonously decreasing functions in which the P concentration monotonously decreases with depth. In this way, P atoms in the channel semiconductor layer 34 can have a concentration gradient in the Z direction.

As described above, the P concentration in the channel semiconductor layer 34 is preferably 1×10¹⁸ cm⁻³ or more at a position where the depth from the upper end of the channel semiconductor layer 34 is 300 nm, or more preferably 1×10¹⁹ cm⁻³ or more at a position where the depth from the upper end of the channel semiconductor layer 34 is 200 nm. Therefore, when the P concentration profile in the channel semiconductor layer 34 is set as shown by the curve A1, the P concentration at a depth of 300 nm of the curve A1 is preferably set to 1×10¹⁸ cm⁻³ or more. The same applies to a case where the P concentration profile in the channel semiconductor layer 34 is set as shown by any one of the curves A2 to A5. The P concentration profile in the channel semiconductor layer 34 of the present embodiment is set so as to follow, for example, a Gaussian distribution.

In FIG. 9A, the P concentration at a depth of 0 nm of the curves A1 to A5 is set to 1×10²⁰ cm⁻³ but the P concentration may be set to other values.

The vertical axis in FIG. 9B represents concentration of P atoms (P concentration) at each point in the semiconductor layer 37 or the most upper insulating layer 32 in FIG. 1. The horizontal axis in FIG. 9B represents a depth from the top surface of the semiconductor layer 37 at each point in the semiconductor layer 37 or the most upper insulating layer 32 in FIG. 1. This depth direction is also parallel to the Z direction. As described above, a case is assumed in the graph in FIG. 9B where a thickness of the most upper insulating layer 32 is set larger than thicknesses of other insulating layers 32.

A curve B1 in FIG. 9B shows an example of the P concentration profile in the semiconductor layer 37 or the most upper insulating layer 32. The P concentration profile in the semiconductor layer 37 or the most upper insulating layer 32 may be set to any shape, and can be set, for example, to a shape of the curve B1.

According to the curve B1, the P concentration in the semiconductor layer 37 is as high as 1×10¹⁹ cm⁻³ or more at any point. Such a P concentration can be achieved, for example, by setting a high acceleration voltage of ion implantation. In this case, not only the P concentration in the semiconductor layer 37 but also the P concentration in the most upper insulating layer 32 increases. Setting a high acceleration voltage of ion implantation causes the most upper insulating layer 32 in the finished semiconductor device (furthermore the other insulating layers 32) to include P atoms. According to the curve B1, the P concentration in the most upper insulating layer 32 decreases with depth. The P concentration profile in the semiconductor layer 37 or the most upper insulating layer 32 of the present embodiment is set so as to follow, for example, a Gaussian distribution. In this way, P atoms in the semiconductor layer 37 or the most upper insulating layer 32 can have a concentration gradient in the Z direction.

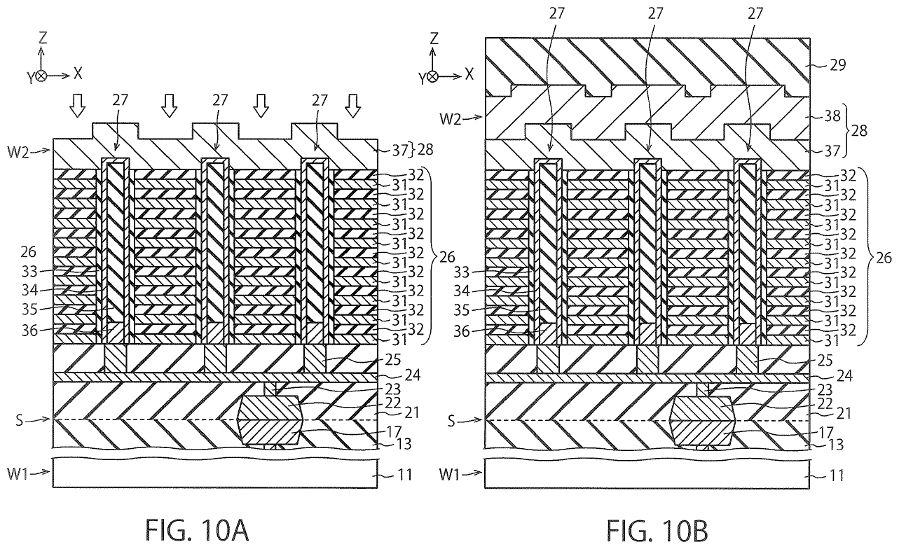

FIGS. 10A and 10B illustrate cross-sectional views showing a method of manufacturing a semiconductor device of a modification of the first embodiment.

Steps in FIGS. 10A and 10B correspond to the steps in FIGS. 7A and 7B respectively. The semiconductor layer 37 in FIG. 6B may also be formed so as to include a concavo-convex top surface due to protruding portions of the columnar portions 27. FIG. 10A illustrates the semiconductor layer 37 formed in such a way. In this case, ion implantation and annealing are performed on the semiconductor layer 37 (FIG. 10A), and furthermore, laser annealing is performed on the semiconductor layer 37 (FIG. 10B). After that, the metal layer 38 is formed on the semiconductor layer 37, the insulator 29 is formed on the metal layer 38 and a top surface of the insulator 29 is flattened by CMP. CMP may be omissible.

As described above, in the present embodiment, the semiconductor layer 37 is formed, P atoms are then introduced into the semiconductor layer 37 and the semiconductor layer 37 is then annealed. Therefore, according to the present embodiment, it is possible to desorb H atoms from the semiconductor layer 37 through low-temperature annealing. Furthermore, according to the present embodiment, introducing P atoms to desorb H atoms makes it possible to introduce P atoms into the semiconductor layer 37 and the channel semiconductor layer 34, and thereby improve the performance of the semiconductor layer 37 and the channel semiconductor layer 34.

In this way, according to the present embodiment, it is possible to optimize influences of impurity atoms (P atoms and H atoms) on the performance of the semiconductor device. For example, it is possible to suppress the problem caused by H atoms while enjoying merits of P atoms. The technique of the present embodiment is applicable to impurity atoms other than P atoms and H atoms.

### Second Embodiment

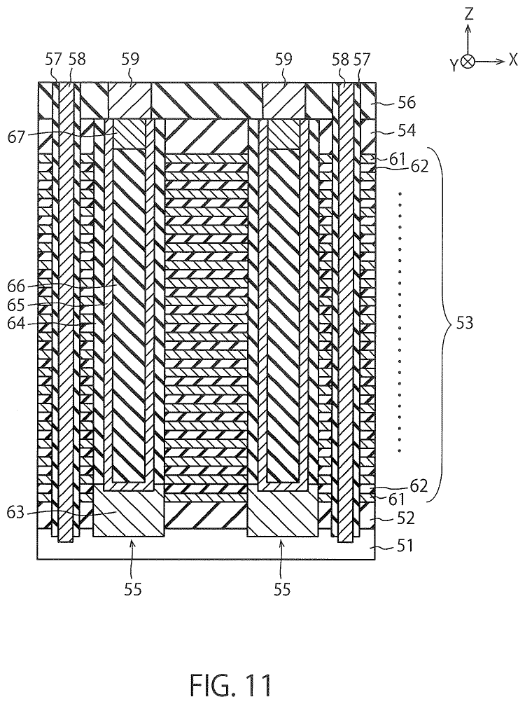

FIG. 11 is a cross-sectional view showing a structure of a semiconductor device of a second embodiment. The semiconductor device of the present embodiment is, for example, a three-dimensional flash memory but has a structure different from the semiconductor device of the first embodiment (FIG. 1). Hereinafter, the structure of the semiconductor device of the present embodiment will be described focusing on differences from the structure of the semiconductor device of the first embodiment.

As illustrated in FIG. 11, the semiconductor device of the present embodiment includes a substrate 51, an inter layer dielectric 52, a stacked film 53, an inter layer dielectric 54, a plurality of columnar portions 55, an inter layer dielectric 56, a plurality of sets of insulator 57 and interconnect layer 58 and a plurality of contact plugs 59. The inter layer dielectric 56 is an example of a first insulator.

Furthermore, the stacked film 53 includes a plurality of electrode layers 61 and a plurality of insulating layers 62. Each columnar portion 55 includes a semiconductor layer 63, a memory insulator 64, a channel semiconductor layer 65, a core insulator 66 and a core semiconductor layer 67. The channel semiconductor layer 65 is an example of a first semiconductor layer.

The substrate 51 is a semiconductor substrate such as a Si substrate. The inter layer dielectric 52 is formed on the substrate 51. The inter layer dielectric 52 is, for example, a SiO₂ film.

The stacked film 53 is provided on the inter layer dielectric 52 and includes a plurality of electrode layers 61 and a plurality of insulating layers 62 alternately stacked in the Z direction. The electrode layer 61 is a metal layer including, for example, a W layer and functions as a word line. The insulating layer 62 is, for example, a SiO₂ film. The inter layer dielectric 54 is formed on the stacked film 53. The inter layer dielectric 54 is, for example, a SiO₂ film.

Each columnar portion 55 is provided in the inter layer dielectric 52, the stacked film 53 and the inter layer dielectric 54, and includes the semiconductor layer 63, the memory insulator 64, the channel semiconductor layer 65, the core insulator 66 and the core semiconductor layer 67.

The semiconductor layer 63 is provided in the inter layer dielectric 52 and the stacked film 53 on the substrate 51 and electrically connected to the substrate 51. The semiconductor layer 63 forms a base of each columnar portion 55 and has a bar-like shape extending in the Z direction. The memory insulator 64 is formed on side surfaces of the stacked film 53 and the inter layer dielectric 54, and has a tubular shape extending in the Z direction. The channel semiconductor layer 65 is formed on a side surface of the memory insulator 64 and a top surface of the semiconductor layer 63, and has a tubular shape extending in the Z direction. The channel semiconductor layer 65 is electrically connected to the semiconductor layer 63. The core insulator 66 is formed on a side surface and a top surface of the channel semiconductor layer 65, and has a bar-like shape extending in the Z direction. The core semiconductor layer 67 is formed on a side surface of the channel semiconductor layer 65 and a top surface of the core insulator 66, and has a bar-like shape extending in the Z direction. The core semiconductor layer 67 is electrically connected to the channel semiconductor layer 65.

The semiconductor layer 63 is, for example, a single crystal silicon layer formed by epitaxial growth from the substrate 61. As will be described later, the memory insulator 64 includes, for example, a block insulator, a charge storage layer and a tunnel insulator in order. The block insulator is, for example, a SiO₂ film. The charge storage layer is, for example, a SiN film. The tunnel insulator is, for example, a SiO₂ film or a SiON film. The channel semiconductor layer 65 is, for example, a polysilicon layer. The core insulator 66 is, for example, a SiO₂ film. The core semiconductor layer 66 is, for example, a polysilicon layer. Each memory cell of the three-dimensional flash memory of the present embodiment is constructed of the channel semiconductor layer 65, the charge storage layer and the electrode layer 61 or the like.

The inter layer dielectric 56 is formed on the inter layer dielectric 54 and the columnar portion 55. The inter layer dielectric 56 is, for example, a silicon oxide film. The insulator 57 and the interconnect layer 58 in each set are formed in order in the inter layer dielectric 52, the stacked film 53, the inter layer dielectric 54 and the inter layer dielectric 56, and extend in the Z direction. The interconnect layer 58 is electrically connected to the substrate.

The contact plugs 59 are provided in the inter layer dielectric 56 and disposed on the columnar portions 55. Each contact plug 59 is formed on the core semiconductor layer 67 of the corresponding columnar portion 55, and thereby electrically connected to the core semiconductor layer 67, the channel semiconductor layer 65, the semiconductor layer 63 and the substrate 51. The contact plug 59 is an example of a plug.

Here, impurity atoms included in the semiconductor device of the present embodiment will be described.

The inter layer dielectric 56 of the present embodiment includes predetermined impurity atoms. The impurity atoms are, for example, H (hydrogen) atoms. According to the present embodiment, the impurity atoms are also included in the channel semiconductor layer 65. The reason why the inter layer dielectric 56 and the channel semiconductor layer 65 of the present embodiment include the same impurity atoms will be described later.

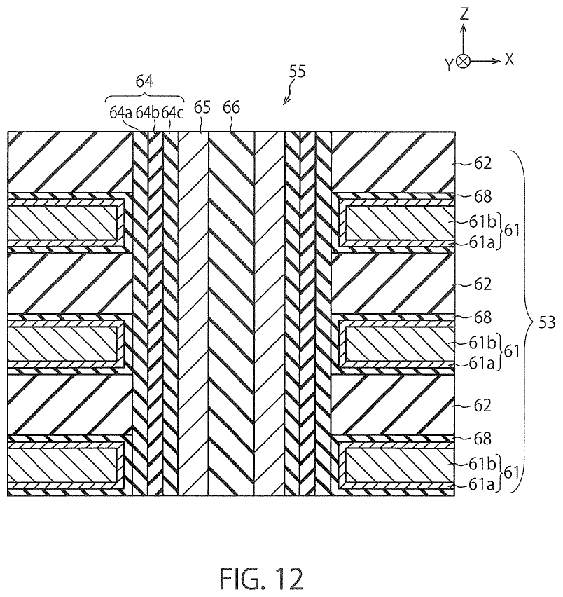

FIG. 12 is an enlarged cross-sectional view showing a structure of the semiconductor device of the second embodiment.

FIG. 12 illustrates three electrode layers 61 and three insulating layers 62 included in the stacked film 53, and one columnar portion 55 provided in the stacked film 53. The memory insulator 64 in the columnar portion 55 includes a block insulator 64a, a charge storage layer 64b and a tunnel insulator 64c formed in order on a side surface of the stacked film 53 as described above. The block insulator 64a is, for example, a SiO₂ film. The charge storage layer 64b is, for example, a SiN film. The tunnel insulator 64c is, for example, a SiO₂ film or a SiON film.

On the other hand, each electrode layer 61 includes a barrier metal layer 61a and an electrode member layer 61b. The barrier metal layer 61a is, for example, a TiN film. The electrode member layer 61b is, for example, a W layer. Each electrode layer 61 of the present embodiment is formed on an undersurface of the insulating layer 62 above, a top surface of the insulating layer 62 below and a side surface of the block insulator 64a via the block insulator 68 as illustrated in FIG. 12. The block insulator 68 is, for example, an Al₂O₃ film and functions as a block insulator of each memory cell together with the block insulator 64a. In this way, the stacked film 53 of the present embodiment includes the block insulator 68 in addition to the electrode layer 61 and the insulating layer 62. The block insulator 68, the barrier metal layer 61a and the electrode member layer 61b are formed in order on the undersurface of the insulating layer 62 above, the top surface of the insulating layer 62 below and the side surface of the block insulator 64a.

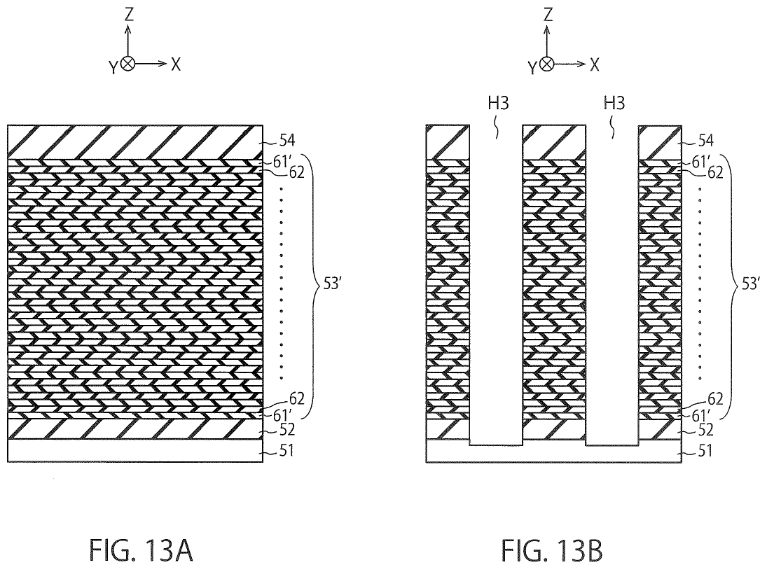

FIGS. 13A to 21B illustrate cross-sectional views showing a method of manufacturing the semiconductor device of the second embodiment.

First, the inter layer dielectric 52 is formed on the substrate 51, and a plurality of sacrificial layers 61′ and a plurality of insulating layers 62 are alternately formed on the inter layer dielectric 52 (FIG. 13A). As a result, a stacked film 53′ is formed on the inter layer dielectric 52. The stacked film 53′ includes the plurality of sacrificial layers 61′ and the plurality of insulating layers 62 alternately stacked in the Z direction. The sacrificial layer 61′ is, for example, SIN. Next, an inter layer dielectric 54 is formed on the stacked film 53′ (FIG. 13A).

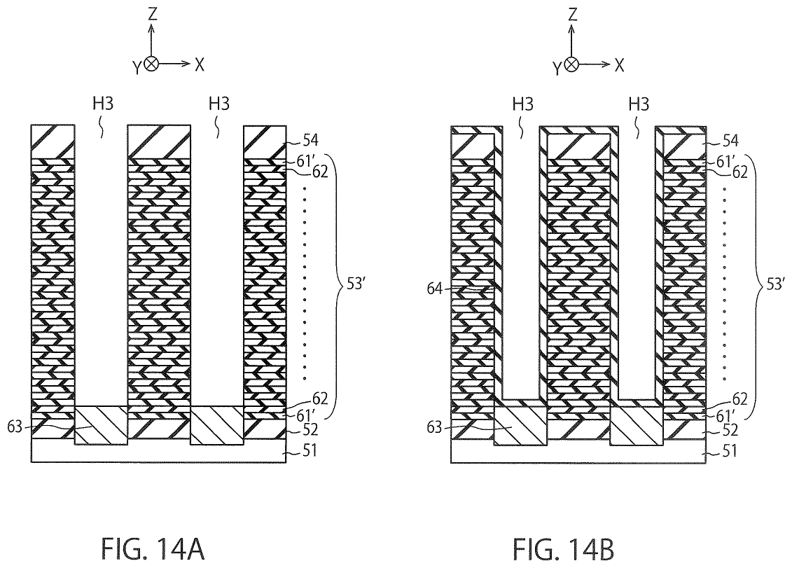

Next, a plurality of memory holes H3 that penetrate the inter layer dielectric 52, the stacked film 53′ and the inter layer dielectric 54 are formed (FIG. 13B). As a result, the surface of the substrate 51 is exposed in the memory holes H3. Next, the semiconductor layer 63 is formed on the substrate 51 in each memory hole H3 by epitaxial growth from the substrate 51 (FIG. 14A).

Next, the memory insulator 64 is formed on a whole surface of the substrate 51 (FIG. 14B). As a result, the memory insulator 64 is formed inside or outside the memory holes H3, and more specifically, the memory insulator 64 is formed on the top surface of the semiconductor layer 63, side surfaces of the stacked film 53′ and the inter layer dielectric 54 and the top surface of the inter layer dielectric 54. The memory insulator 64 is formed by forming the block insulator 64a, the charge storage layer 64b and the tunnel insulator 64c in order on the whole surface of the substrate 51 (see FIG. 12).

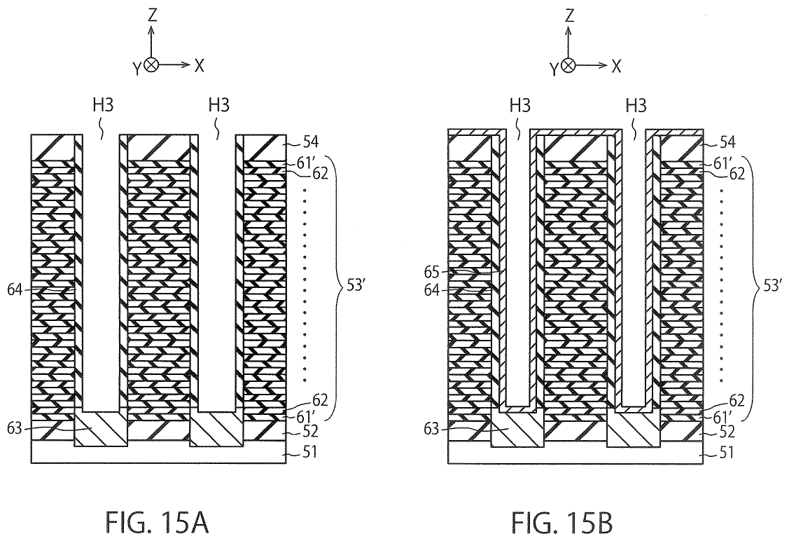

Next, the memory insulator 64 is removed from the top surface of the semiconductor layer 63 or from the top surface of the inter layer dielectric 54 (FIG. 15A). As a result, the top surface of the semiconductor layer 63 is exposed in each memory hole H3.

Next, the channel semiconductor layer 65 is formed on the whole surface of the substrate 51 (FIG. 15B). As a result, the channel semiconductor layer 65 is formed inside or outside the memory holes H3, more specifically, formed on a top surface of the semiconductor layer 63, a side surface of the memory insulator 64 and a top surface of the inter layer dielectric 54.

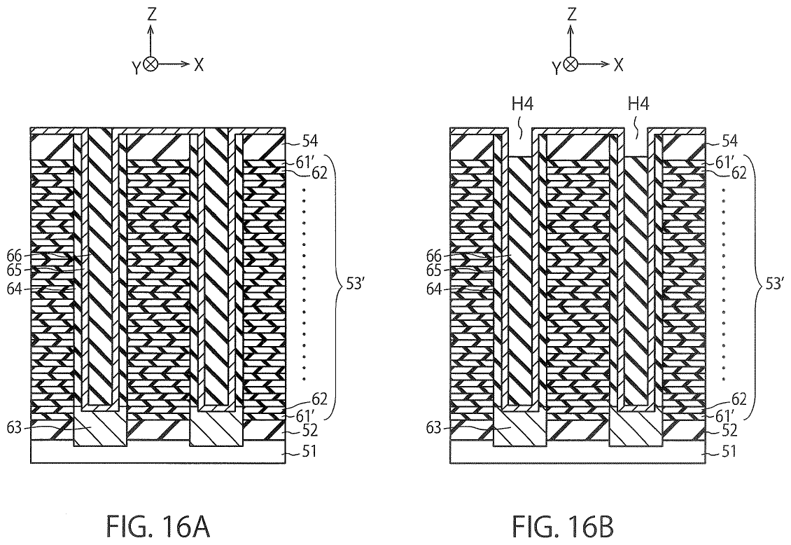

Next, the core insulator 66 is embedded in each memory hole H3 (FIG. 16A). As a result, the core insulator 66 is formed on a top surface or a side surface of the channel semiconductor layer 65 in each memory hole H3.

Next, a portion of the core insulator 66 in each memory hole H3 is removed by etch back (FIG. 16B). As a result, a concave portion H4 is formed on the core insulator 66 in each memory hole H3.

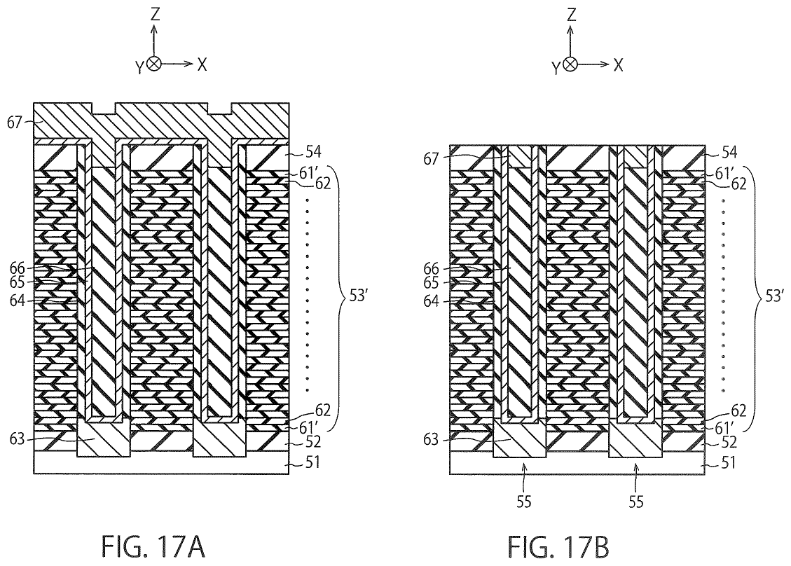

Next, the core semiconductor layer 67 is formed on the whole surface of the substrate 51 (FIG. 17A). As a result, a portion of the core semiconductor layer 67 is formed in each concave portion H4. In the step in FIG. 17A, the core semiconductor layer 67 is formed as an amorphous semiconductor layer, crystallized in a subsequent step and changed to a polycrystal semiconductor layer. This amorphous semiconductor layer is, for example, an a-Si (amorphous silicon) layer.

Next, the core semiconductor layer 67 outside the concave portion H4 is removed by RIE (reactive ion etching) (FIG. 17B). As a result, the plurality of columnar portions 55 extending in the Z direction are formed in the plurality of memory holes H3. Each columnar portion 55 is formed so as to include the semiconductor layer 63, the memory insulator 64, the channel semiconductor layer 65, the core insulator 66 and the core semiconductor layer 67.

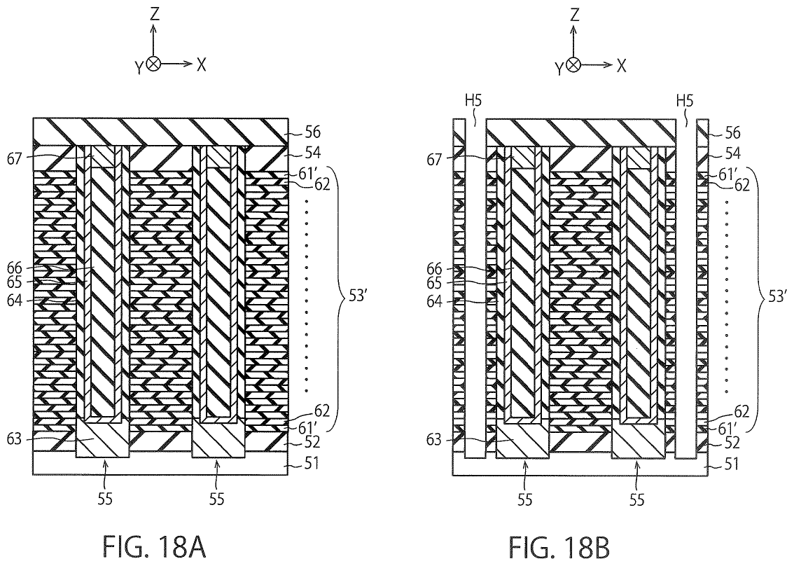

Next, the inter layer dielectric 56 is formed on the inter layer dielectric 54 and the columnar portions 55 (FIG. 18A). Next, a plurality of slits H5 that penetrate the inter layer dielectric 52, the stacked film 53′, the inter layer dielectric 54 and the inter layer dielectric 56 are formed by RIE (FIG. 18B).

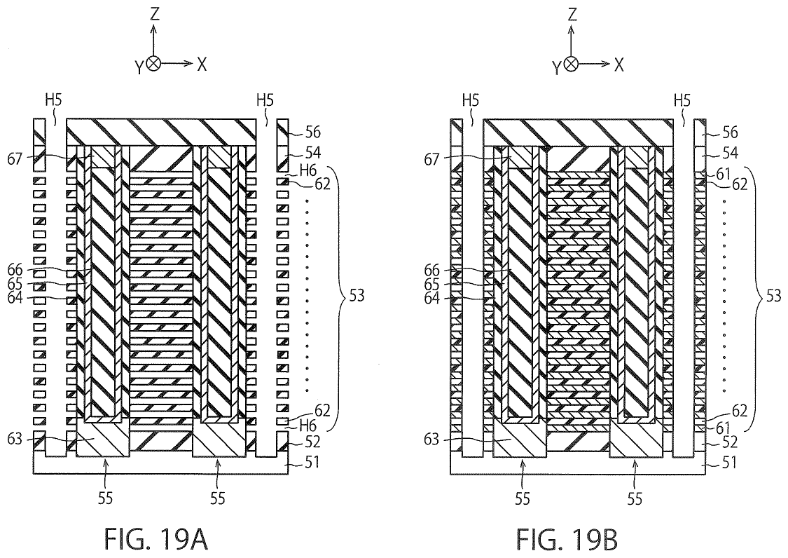

Next, the sacrificial layer 61′ is removed by wet etching using the slits H5 (FIG. 19A). As a result, a plurality of cavities H6 are formed between the insulating layers 62 in the stacked film 53′.

Next, the plurality of electrode layers 61 are formed from the slits H5 in the cavities H6 (FIG. 19B). As a result, the stacked film 53 including the plurality of electrode layers 61 and the plurality of insulating layers 62 alternately stacked in the Z direction is formed between the inter layer dielectric 52 and the inter layer dielectric 54. Furthermore, a structure in which the plurality of columnar portions 55 penetrate the inter layer dielectric 52, the stacked film 53, and the inter layer dielectric 54 is formed on the substrate 51. In FIG. 19B, the inter layer dielectric 56 is provided on the columnar portions 55 and provided on the stacked film 53 via the inter layer dielectric 54. When the electrode layer 61 is formed in each cavity H6, the block insulator 68, the barrier metal layer 61a and the electrode member layer 61b are formed in order in each cavity H6 (see FIG. 12).

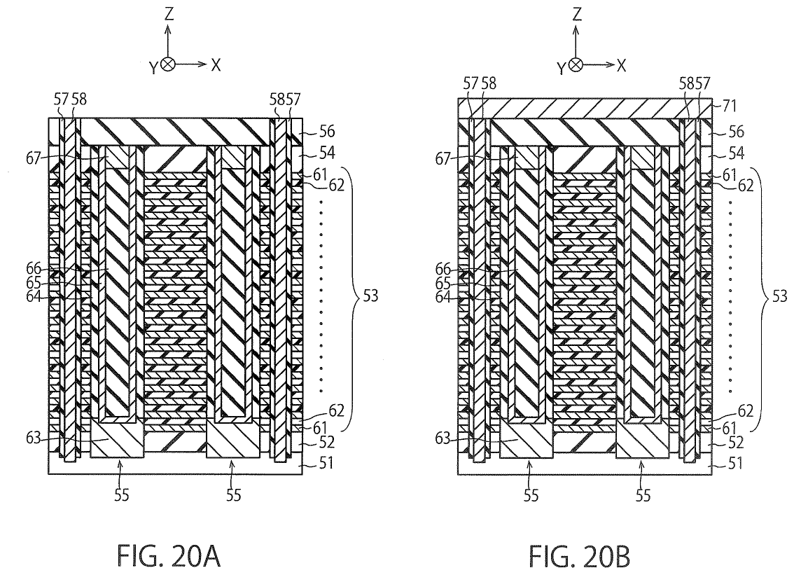

Next, the insulator 57 is formed in each slit H5, the insulator 57 is removed from the base of each slit H5, and then the interconnect layer 58 is formed in each slit H5 (FIG. 20A). As a result, the plurality of sets of the insulator 57 and the interconnect layer 58 are formed in the plurality of slits H5. The interconnect layer 58 in each slit H5 is electrically connected to the substrate 51.

Next, a semiconductor layer 71 is formed on the inter layer dielectric 56, the insulator 57 and the interconnect layer 58 (FIG. 20B). In the step in FIG. 20B, the semiconductor layer 71 is formed as an amorphous semiconductor layer. This amorphous semiconductor layer is, for example, an a-Si layer. In the present embodiment, the semiconductor layer 71 as the a-Si layer is formed using a source gas including elements of Si and H. Therefore, the semiconductor layer 71 formed in the step in FIG. 20B includes H atoms as impurity atoms. The semiconductor layer 71 is an example of a first film.

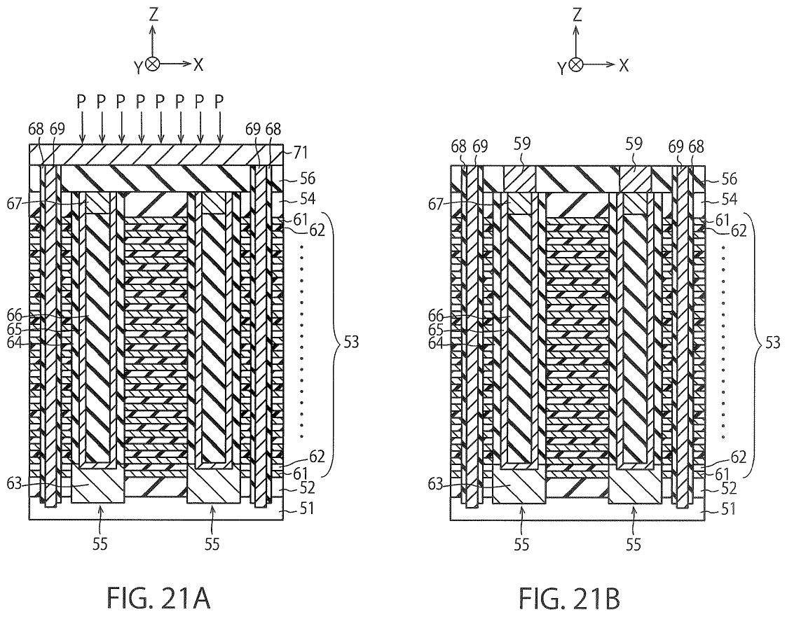

Next, ion implantation into the semiconductor layer 71 is performed using P (phosphor) ions (FIG. 21A). As a result, P atoms are introduced into the semiconductor layer 71 as impurity atoms. A semiconductor layer 37 has been described in the first embodiment. P atoms have an effect of promoting desorption of H atoms from the semiconductor layer 71. As will be described later, in the present embodiment, H atoms desorbed from the semiconductor layer 71 are effectively used to terminate dangling bonds.

The semiconductor layer 71 may be formed for any purpose. For example, the semiconductor layer 71 may be formed for use as an interconnect layer on the substrate 51 or may be formed for use as a hard mask layer in the manufacturing step of the semiconductor device. In the former case, the semiconductor layer 71 remains in the finished semiconductor device, whereas in the latter case, the semiconductor layer 71 does not remain in the finished semiconductor device. The semiconductor layer 71 of the present embodiment is formed as a hard mask layer to process a layer (not illustrated) on the substrate 51, and so the semiconductor layer 71 does not remain in the finished semiconductor device as will be described later. Therefore, in the present embodiment, a metal layer, an insulator or a stacked film may be formed as the hard mask layer instead of the semiconductor layer 71.

As ions used for ion implantation, other ions may also be used, which can promote desorption of H atoms from the semiconductor layer 71. Such ions are, for example, B (boron) ions, As (arsenic) ions, Si (silicon) ions, or O (oxygen) ions. For example, when the semiconductor layer 71 is used as an interconnect layer, Si ions may be implanted into the Si-based semiconductor layer 71. In this case, since both the semiconductor layer 71 and ions are made of Si element, it is possible to reduce adverse influences of ions on the semiconductor layer 71. On the other hand, when the semiconductor layer 71 is used as an interconnect layer, the semiconductor layer 71 may be used as a p-type semiconductor layer or an n-type semiconductor layer by implanting P ions, B ions, or As ions into the semiconductor layer 71.

Ion implantation of the present embodiment is performed using, for example, a high-energy ion implanter with implantation energy on the order of 60 keV or less. The amount of dose of ion implantation of the present embodiment is set to, for example, 1×10¹⁵ cm⁻² or more.

Next, the semiconductor layer 71 is annealed to desorb H atoms from the semiconductor layer 71 (FIG. 21A). As a result, at least some H atoms in the semiconductor layer 71 are desorbed from the semiconductor layer 71 and the concentration of H atoms in the semiconductor layer 71 decreases.

In the present embodiment, H atoms desorbed from the semiconductor layer 71 are introduced into the channel semiconductor layer 65. The channel semiconductor layer 65 of the present embodiment is a polysilicon layer and includes dangling bonds of Si atoms. According to the present embodiment, it is possible to terminate dangling bonds in the channel semiconductor layer 65 with H atoms desorbed from the semiconductor layer 71. It is thereby possible to improve reliability of the channel semiconductor layer 65 and the memory cell. As a result, the channel semiconductor layer 65 of the present embodiment includes H atoms as impurity atoms in the finished semiconductor device.

Dangling bonds can further be present in high density at an interface between the channel semiconductor layer 65 and the tunnel insulator 64c (see FIG. 12). In the present embodiment, H atoms desorbed from the semiconductor layer 71 reach the interface between the channel semiconductor layer 65 and the tunnel insulator 64c as well. According to the present embodiment, H atoms desorbed from the semiconductor layer 71 can terminate dangling bonds at the interface between the channel semiconductor layer 65 and the tunnel insulator 64c. As a result, H atoms can also be included at the interface between the channel semiconductor layer 65 and the tunnel insulator 64c in the finished semiconductor device or in the tunnel insulator 64c.

In the present embodiment, H atoms desorbed from the semiconductor layer 71 reach the channel semiconductor layer 65 or the tunnel insulator 64c via the inter layer dielectric 56. Therefore, H atoms desorbed from the semiconductor layer 71 are also present in the inter layer dielectric 56 in the finished semiconductor device of the present embodiment. According to the present embodiment, since the undersurface of the semiconductor layer 71 is in contact with the top surface of the inter layer dielectric 56 over a wide region, H atoms desorbed from the semiconductor layer 71 can be easily introduced into the inter layer dielectric 56. In the finished semiconductor device of the present embodiment, H atoms desorbed from the semiconductor layer 71 may be further present in the inter layer dielectric 54 or at least the most upper insulating layer 62 among the aforementioned plurality of insulating layers 62. H atoms in the semiconductor layer 71, the inter layer dielectric 56, the channel semiconductor layer 65 and the tunnel insulator 64c of the present embodiment can have a concentration gradient in the Z direction for the same reason as P atoms in the semiconductor layer 37, the most upper insulating layer 32 and the channel semiconductor layer 34 of the first embodiment.

The temperature at which the semiconductor layer 71 is annealed (anneal temperature) may be any temperature. It is preferable to set the anneal temperature to a high temperature to efficiently desorb H atoms from the semiconductor layer 71. On the other hand, when the anneal temperature is too high, annealing may adversely affect the metal layer in the semiconductor device. Therefore, the anneal temperature may be preferably set to a high temperature that does not adversely affect the metal layer. The anneal temperature of the semiconductor layer 71 of the present embodiment is set, for example, to 400° C. to 500° C.

When the semiconductor layer 71 of the present embodiment is formed as a hard mask layer to process a layer (not illustrated) on the substrate 51, the semiconductor layer 71 is removed when this process ends and after the step in FIG. 21A ends (FIG. 21B). Furthermore, an opening is formed on the columnar portion 55 in the inter layer dielectric 56 and the contact plug 59 is formed in the opening (FIG. 21B). As a result, each contact plug 59 is formed on the core semiconductor layer 67 of the corresponding columnar portion 55 and electrically connected to the core semiconductor layer 67.

After that, various interconnect layers, plugs, inter layer dielectrics or the like are formed on the substrate 51. The semiconductor device in FIG. 11 is manufactured in this way.

Here, the semiconductor layer 71 of the present embodiment will be described in further detail.

According to the present embodiment, dangling bonds are terminated using H atoms desorbed from the semiconductor layer 71. This makes it possible to improve reliability of the channel semiconductor layer 65 and the tunnel insulator 64c or reliability of the memory cell including the channel semiconductor layer 65 and the tunnel insulator 64c.

In the present embodiment, the semiconductor layer 71 for a hard mask is also used to terminate dangling bonds. Therefore, according to the present embodiment, the semiconductor layer 71 can be effectively used for these two purposes. That is, it is possible to remove the semiconductor layer 71 after using it to terminate dangling bonds as well instead of removing the semiconductor layer 71 after using it only for a hard mask. However, the semiconductor layer 71 may also be used only for termination of dangling bond in the present embodiment.

In the present embodiment, the semiconductor layer 71 includes H atoms from the time when the semiconductor layer 71 is formed. However, H atoms may be introduced into the semiconductor layer 71 by heat treatment or plasma processing or the like after the semiconductor layer 71 is formed. In this case, after H atoms are introduced into the semiconductor layer 71, ion implantation or annealing in the step in FIG. 21A is performed.

In the present embodiment, an insulator may be formed on the semiconductor layer 71 between the ion implantation and annealing in the step in FIG. 21A. It is thereby possible to prevent H atoms in the semiconductor layer 71 from being released from the top surface of the semiconductor layer 71 during annealing and make it easier for H atoms to be released from the undersurface of the semiconductor layer 71. In other words, the insulator can prevent H atoms from diffusing upward. As a result, it is possible to more efficiently terminate dangling bonds. In this case, the insulator preferably has barrier property to diffusion of H atoms. Examples of such an insulator include a SiN film and an Al₂O₃ film. On the contrary, in the present embodiment, a semiconductor layer or a metal layer having barrier property to diffusion of H atoms may be formed on the semiconductor layer 71 instead of the insulator. In a third embodiment, which will be described later, an example of using a barrier layer 99 having barrier property to diffusion of H atoms will be described.

The semiconductor layer 71 of the present embodiment may also include atoms other than H atoms capable of terminating dangling bonds. Examples of such atoms include F (fluorine) atoms and CI (chlorine) atoms. H atoms in the semiconductor layer 71 may be normal ¹H atoms (light hydrogen atoms) or ²H atoms (deuterium atoms: D atoms). When using any impurity atoms, the impurity atoms may be included in the semiconductor layer 71 from the time when the semiconductor layer 71 is formed or may be introduced into the semiconductor layer 71 after forming the semiconductor layer 71. For example, when the semiconductor layer 71 includes F atoms, F atoms desorbed from the semiconductor layer 71 are introduced into the channel semiconductor layer 65 or the like, dangling bonds are terminated and included in the channel semiconductor layer 65 or the like of a finished semiconductor device.

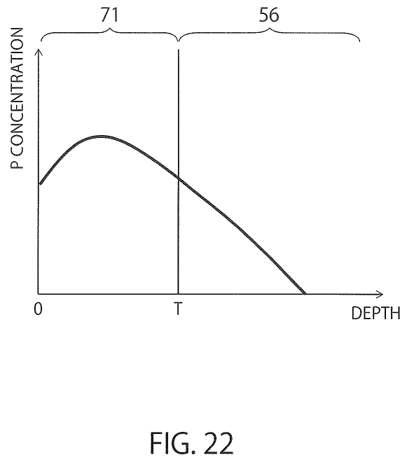

P atoms of the present embodiment are introduced into the semiconductor layer 71 by ion implantation in the step in FIG. 21A. In this case, there is a possibility that P atoms may be introduced into layers other than the semiconductor layer 71. Regarding ion implantation of the present embodiment, there is a possibility that P atoms may be introduced into the inter layer dielectric 56, the inter layer dielectric 54, the channel semiconductor layer 65, the core semiconductor layer 67 or at least the most upper insulating layer 62 among the plurality of insulating layers 62. In this case, P atoms are included in the inter layer dielectric 56 or the like of the finished semiconductor device. For example, when P atoms are introduced into the channel semiconductor layer 65 or the core semiconductor layer 67, it is thereby possible to improve the performance of the channel semiconductor layer 65 and the core semiconductor layer 67. Such P atoms will be described further with reference to FIG. 22.

FIG. 22 is a graph describing a concentration of P (phosphorus) atoms included in the semiconductor layer 71 or the like of the second embodiment.

The vertical axis in FIG. 22 represents the concentration of P atoms (P concentration) at each point in the semiconductor layer 71 or the inter layer dielectric 56 in FIG. 21A. The horizontal axis in FIG. 22 represents a depth from the top surface of the semiconductor layer 71 at each point in the semiconductor layer 71 or the inter layer dielectric 56 in FIG. 21A. Reference character T denotes a thickness of the semiconductor layer 71. The depth direction in FIG. 22 is parallel to the Z direction.

A curve in FIG. 22 illustrates an example of a P concentration profile in the semiconductor layer 71 or the inter layer dielectric 56. The P concentration profile has a shape similar to the P concentration profile of the curve B1 in FIG. 9B. More specifically, the P concentration in the inter layer dielectric 56 decreases with depth. In the finished semiconductor device of the present embodiment, as a trace of the fact that the step in FIG. 21A has been executed, the inter layer dielectric 56 includes P atoms having the P concentration profile as illustrated in FIG. 22. The same also applies to a case where layers other than the inter layer dielectric 56 include P atoms. In this way, P atoms in the semiconductor layer 71 or in the inter layer dielectric 56 may have a concentration gradient in the Z direction.

After the step in FIG. 21A, when P atoms in the inter layer dielectric 56 spread greatly, the P concentration profile in the inter layer dielectric 56 in the finished semiconductor device may greatly change from the P concentration profile in FIG. 22. On the other hand, when P atoms in the inter layer dielectric 56 do not spread so much after the step in FIG. 21A, the P concentration profile in the inter layer dielectric 56 of the finished semiconductor device is similar to the P concentration profile in FIG. 22.

As described above, in the present embodiment, the semiconductor layer 71 is formed, P atoms are then introduced into the semiconductor layer 71 and the semiconductor layer 71 is then annealed. Therefore, according to the present embodiment, it is possible to introduce H atoms into the channel semiconductor layer 65 or the like by the H atoms desorbed from the semiconductor layer 71 and terminate dangling bonds of the channel semiconductor layer 65 or the like. This makes it possible to improve reliability of the channel semiconductor layer 65 or the like.

In this way, according to the present embodiment, it is possible to optimize influences of impurity atoms (P atoms or H atoms) on the performance of the semiconductor device. For example, it is possible to generate H atoms for termination of dangling bonds using P atoms or cause the H atoms generated in this way to terminate dangling bonds. As described above, the technique of the present embodiment may be applied to impurity atoms other than P atoms or H atoms as well. Atoms to be introduced into the semiconductor layer 71 may be other than impurity atoms as in the aforementioned Si atoms.

### Third Embodiment

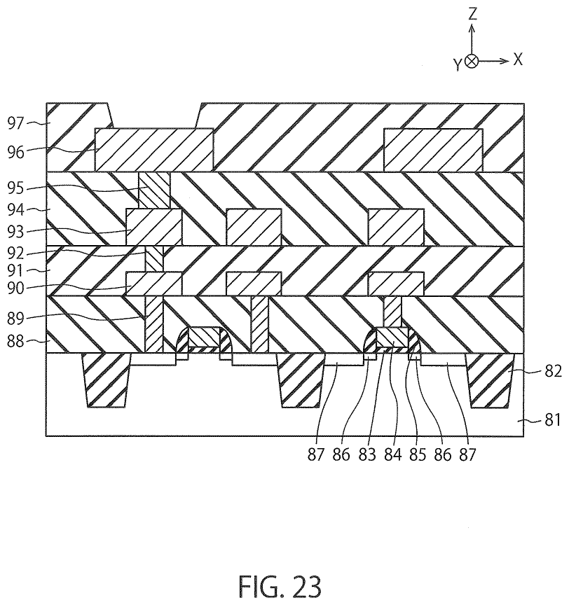

FIG. 23 is a cross-sectional view showing a structure of a semiconductor device of a third embodiment. The semiconductor device of the present embodiment includes a plurality of planar transistors. Hereinafter, a structure of the semiconductor device of the present embodiment will be described focusing on differences from the structures of the semiconductor devices of the first and second embodiments.

The semiconductor device in FIG. 23 includes a substrate 81, a plurality of isolation regions 82, a gate insulator 83 and a gate electrode 84 of each transistor, a plurality of sidewall insulators 85, a plurality of extension regions 86 and a plurality of source/drain regions 87, an inter layer dielectric 88, a plurality of contact plugs 89, an interconnect layer 90 including a plurality of interconnects, an inter layer dielectric 91, a via plug 92, an interconnect layer 93 including a plurality of interconnects, an inter layer dielectric 94, a via plug 95, an interconnect layer 96 including a plurality of interconnects and a passivation film 97.

The substrate 81 is, for example, a semiconductor substrate such as a Si substrate. The substrate 81 may be any semiconductor substrate other than the Si substrate or may be a SOI (silicon on insulator) substrate. The isolation regions 82 are formed in the substrate 81 to separate the transistors from each other. The isolation regions 82 are also called “STI” (shallow trench isolation).

Each transistor includes a gate insulator 83 and a gate electrode 84 formed in order on the substrate 81. The gate insulator 83 is, for example, a SiO₂ film or a high dielectric constant film (High-k film). The gate electrode 84 is a stacked film including, for example, a polysilicon layer, a metal layer or a polysilicon layer and a metal layer. The sidewall insulator 85 is formed on a side surface of the gate electrode 84 on the substrate 81. The extension regions 86 are formed in the substrate 81 so as to sandwich the gate electrode 84. The source/drain regions 87 are also formed in the substrate 81 so as to sandwich the gate electrode 84. However, the extension region 86 are sandwiched between the source/drain regions 87. Each transistor formed on the substrate 81 may be an Fin FET or a nanowire FET.

The inter layer dielectric 88 is formed on the substrate 81 so as to cover each transistor. The inter layer dielectric 88 is a stacked film including, for example, a SiO₂ film or a SiO₂ film and other insulators. The contact plugs 89 are formed in the inter layer dielectric 88 and disposed on the gate electrode 84 and on the source/drain regions 87.

The interconnect layer 90 is formed on the contact plug 89 in the inter layer dielectric 88. The interconnect layer 90 is, for example, a metal layer. The inter layer dielectric 91 is formed on the inter layer dielectric 88 so as to cover the interconnect layer 90. The inter layer dielectric 91 is a stacked film including a SiO₂ film or a SiO₂ film and other insulators. The via plug 92 is formed on the interconnect layer 90 in the inter layer dielectric 91.

The interconnect layer 93 is formed on the via plug 92 on the inter layer dielectric 91. The interconnect layer 93 is, for example, a metal layer. The inter layer dielectric 94 is formed on the inter layer dielectric 91 so as to cover the interconnect layer 93. The inter layer dielectric 94 is a stacked film including, for example, a SiO₂ film or a SiO₂ film and other insulators. The via plug 95 is formed on the interconnect layer 93 in the inter layer dielectric 94.

The interconnect layer 96 is formed on the via plug 95 on the inter layer dielectric 94. The interconnect layer 96 is, for example, a metal layer and includes an interconnect that functions as a bonding pad. The passivation film 97 is formed on the inter layer dielectric 94 so as to cover the interconnect layer 96. However, the bonding pad in the interconnect layer 96 is exposed from the passivation film 97. The passivation film 97 is an insulator such as a SiO₂ film.

The semiconductor device of the present embodiment includes three interconnect layers 90, 93 and 96 but may also include four or more interconnect layers. The number of interconnect layers of the semiconductor device of the present embodiment may be any number.

Here, impurity atoms included in the semiconductor device of the present embodiment will be described.

The inter layer dielectric 94 of the present embodiment includes predetermined impurity atoms. These impurity atoms are for example, H (hydrogen) atoms. In the present embodiment, the impurity atoms are further included in the substrate 81 as well. The reason why the inter layer dielectric 94 and the substrate 81 of the present embodiment include the same impurity atoms will be described later.

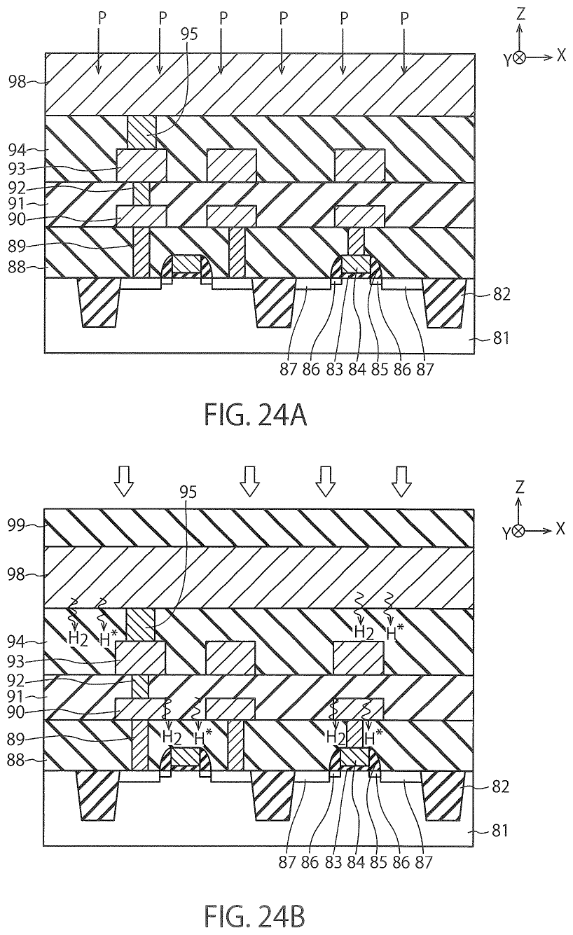

FIGS. 24A and 24B illustrate cross-sectional views showing a method of manufacturing the semiconductor device of the third embodiment.

First, the isolation regions 82 are formed in the substrate 81 and the gate insulator 83 and the gate electrode 84 of each transistor are formed in order on the substrate 81 (FIG. 24A). The isolation regions 82 are formed by forming, for example, trenches in the substrate 81 by dry etching and embedding a SiO₂ film in the trenches.

Next, the extension regions 86 are formed in the substrate 81, the sidewall insulator 85 is formed on the side surface of the gate electrode 84 by etch back and the source/drain regions 87 are formed in the substrate 81 (FIG. 24A). The extension regions 86 and the source/drain regions 87 are formed by, for example, introducing impurity atoms such as P (phosphor), B (boron) and As (arsenic) into the substrate 81.

Next, the inter layer dielectric 88 is formed on the substrate 81 and the contact plugs 89 are formed in the inter layer dielectric 88 (FIG. 24A). Next, the interconnect layer 90 is formed on the inter layer dielectric 88 and the contact plugs 89, the inter layer dielectric 91 is formed on the inter layer dielectric 88 and the interconnect layer 90 and the via plug 92 is formed in the inter layer dielectric 91 (FIG. 24A). Next, the interconnect layer 93 is formed on the inter layer dielectric 91 and the via plug 92, the inter layer dielectric 94 is formed on the inter layer dielectric 91 and the interconnect layer 93 and the via plug 95 is formed in the inter layer dielectric 94 (FIG. 24A).

Next, the semiconductor layer 98 is formed on the inter layer dielectric 94 and the via plug 95 (FIG. 24A). In the step in FIG. 24A, the semiconductor layer 98 is formed as an amorphous semiconductor layer. The amorphous semiconductor layer is, for example, an a-Si layer. In the present embodiment, the semiconductor layer 98 as the a-Si layer is formed using a source gas including elements of Si and H. Therefore, the semiconductor layer 98 formed in the step in FIG. 24A includes H atoms as impurity atoms. The semiconductor layer 98 is an example of a first film.

Next, ion implantation into the semiconductor layer 98 is performed using P (phosphorus) ions (FIG. 24A). As a result, P atoms as impurity atoms are introduced into the semiconductor layer 98. As described about the semiconductor layers 37 and 71 in the first and second embodiments, P atoms have the effect of promoting desorption of H atoms from the semiconductor layer 98. As will be described later, in the present embodiment, H atoms desorbed from the semiconductor layer 98 are effectively used to terminate dangling bonds.

The semiconductor layer 98 may be formed for any purpose. For example, the semiconductor layer 98 may be formed for use as an interconnect layer on the substrate 51 or for use as a hard mask layer in the manufacturing step of the semiconductor device. In the former case, the semiconductor layer 98 remains in a finished semiconductor device, whereas in the latter case, the semiconductor layer 98 does not remain in the finished semiconductor device. The semiconductor layer 98 of the present embodiment is formed as a hard mask layer to process a layer (not illustrated) on the substrate 51, and so the semiconductor layer 98 does not remain in the finished semiconductor device as will be described later. Therefore, in the present embodiment, a metal layer, an insulator or a stacked film may be formed as the hard mask layer instead of the semiconductor layer 98.

As ions to be used for ion implantation, other ions that can promote desorption of H atoms from the semiconductor layer 98 may also be used. Such ions are for example, B (boron) ions, As (arsenic) ions, Si (silicon) ions or O (oxygen) ions.

Ion implantation of the present embodiment is performed using, for example, a high-energy ion implanter with implantation energy on the order of 60 keV or less. The amount of dose of ion implantation of the present embodiment is set to, for example, 1×10¹⁵ cm⁻² or more.

Next, after the insulator 99 is formed on the semiconductor layer 98 and the semiconductor layer 98 is annealed to desorb H atoms from the semiconductor layer 98 (FIG. 24B). As a result, at least some H atoms in the semiconductor layer 98 are desorbed from the semiconductor layer 98 and the concentration of H atoms in the semiconductor layer 98 decreases. The temperature at which the semiconductor layer 98 is annealed (anneal temperature) may be any temperature, and may be set to 400° C. to 500° C., for example. The insulator 99 is an example of a second film.

In the present embodiment, H atoms desorbed from the semiconductor layer 98 are introduced into the substrate 81. The substrate 81 of the present embodiment is a Si substrate and includes dangling bonds of Si atoms in a channel region of a transistor or the like. According to the present embodiment, it is possible to terminate dangling bonds in the substrate 81 with H atoms desorbed from the semiconductor layer 98. It is thereby possible to improve reliability of the channel region and the transistor. As a result, the substrate 81 of the present embodiment includes H atoms as impurity atoms in the finished semiconductor device.

Dangling bonds can be present in high density at an interface between the substrate 81 and the gate insulator 82. In the present embodiment, H atoms s desorbed from the semiconductor layer 98 reach the interface between the substrate 81 and the gate insulator 82 as well. According to the present embodiment, H atoms desorbed from the semiconductor layer 98 can terminate dangling bonds at the interface between the substrate 81 and the gate insulator 82. As a result, H atoms can be included at the interface between the substrate 81 and the gate insulator 82 or in the gate insulator 82 in the finished semiconductor device.

In the present embodiment, H atoms desorbed from the semiconductor layer 98 reach the substrate 81 or the gate insulator 82 via the inter layer dielectric 94. Therefore, H atoms desorbed from the semiconductor layer 98 are also present in the inter layer dielectric 94 in the finished semiconductor device of the present embodiment. According to the present embodiment, since the undersurface of the semiconductor layer 98 is in contact with the top surface of the inter layer dielectric 94 over a wide region, H atoms desorbed from the semiconductor layer 98 can be easily introduced into the inter layer dielectric 94. In the finished semiconductor device of the present embodiment, H atoms desorbed from the semiconductor layer 98 may be further present in the inter layer dielectric 91 or in the inter layer dielectric 88.

In the present embodiment, the insulator 99 is formed on the semiconductor layer 98 before annealing in the step in FIG. 24B. It is thereby possible to prevent H atoms in the semiconductor layer 98 from being released from the top surface of the semiconductor layer 98 during annealing and make it easier for the H atoms to be released from the undersurface of the semiconductor layer 98. In other words, the insulator 99 can prevent the H atoms from diffusing upward. As a result, dangling bonds can be terminated more efficiently. The insulator 99 of the present embodiment has barrier property to diffusion of H atoms. Examples of such an insulator 99 include a SIN film and an Al₂O₃ film. In the present embodiment, a semiconductor layer or a metal layer having barrier property to diffusion of H atoms may be formed on the semiconductor layer 98 instead of the insulator 99.

When the semiconductor layer 98 of the present embodiment is formed as a hard mask layer to process a layer (not illustrated) on the substrate 81, the semiconductor layer 98 is removed when this process ends and after the steps in FIG. 22A and 22B end. In the present embodiment, the insulator 99 is likewise removed before the semiconductor layer 98 is removed.

After that, the interconnect layer 96 is formed on the inter layer dielectric 94 and the via plug 95 and the passivation film 97 is formed on the interconnect layer 96, the passivation film 97 is processed and a bonding pad is exposed from the passivation film 97 (see FIG. 21). The semiconductor device in FIG. 21 is manufactured in this way.

Here, further details of the semiconductor layer 98 of the present embodiment will be described.

In the present embodiment, dangling bonds are terminated using H atoms desorbed from the semiconductor layer 98. This makes it possible to improve reliability of the channel region (substrate 81) and the gate insulator 82 and reliability of the transistor including the channel region and the gate insulator 82.

In the present embodiment, the semiconductor layer 98 for a hard mask is also used to terminate dangling bonds. Therefore, according to the present embodiment, the semiconductor layer 98 can be effectively used for these two purposes. That is, it is possible to remove the semiconductor layer 98 after using it to terminate dangling bonds as well instead of removing the semiconductor layer 98 after using it only for a hard mask. However, the semiconductor layer 98 may also be used only for termination of dangling bond in the present embodiment.

In the present embodiment, the semiconductor layer 98 includes H atoms from the time when the semiconductor layer 98 is formed. However, H atoms may be introduced into the semiconductor layer 98 after the semiconductor layer 98 is formed by heat treatment or plasma processing or the like. In this case, after H atoms are introduced into the semiconductor layer 98, ion implantation in the step of FIG. 24A or annealing in the step in FIG. 24B are performed.

The semiconductor layer 98 of the present embodiment may include atoms other than H atoms capable of terminating dangling bonds. Examples of such atoms include F atoms and Cl atoms. H atoms in the semiconductor layer 71 may be normal ¹H atoms (light hydrogen atoms) or ²H atoms (deuterium atoms: D atoms). When using any impurity atoms, the impurity atoms may be included in the semiconductor layer 98 from the time when the semiconductor layer 98 is formed or may be introduced into the semiconductor layer 98 after forming the semiconductor layer 98. For example, when the semiconductor layer 98 includes F atoms, the F atoms desorbed from the semiconductor layer 98 are introduced into the substrate 81, dangling bonds are terminated and included in the substrate 81 of a finished semiconductor device or the like.

P atoms of the present embodiment are introduced into the semiconductor layer 98 by ion implantation in the step in FIG. 24A. In this case, there is a possibility that P atoms may be introduced into layers other than the semiconductor layer 98. Regarding ion implantation of the present embodiment, there is a possibility that P atoms may also be introduced into inter layer dielectric 94, the inter layer dielectric 88, the gate electrode 84, the substrate 81 or the like. In this case, P atoms are included in the inter layer dielectric 94 of the finished semiconductor device.

As described above, in the present embodiment, the semiconductor layer 98 is formed, P atoms are then introduced into the semiconductor layer 98 and the semiconductor layer 98 is then annealed. Therefore, according to the present embodiment, it is possible to introduce H atoms into the substrate 81 (channel region) or the like by the H atoms desorbed from the semiconductor layer 98 and terminate dangling bonds of the substrate 81 or the like. This makes it possible to improve reliability of the substrate 81 or the like.

In this way, according to the present embodiment, it is possible to optimize influences of impurity atoms (P atoms or H atoms) on the performance of the semiconductor device. For example, it is possible to generate H atoms to terminate dangling bonds using P atoms or cause the H atoms generated in this way to terminate dangling bonds. The technique of the present embodiment may also be applied to impurity atoms other than P atoms or H atoms as well. Atoms to be introduced into the semiconductor layer 98 may be other than impurity atoms as the aforementioned Si atoms.

In the first to third embodiments, atoms used for ion implantation are atoms of types different from the type of atoms to be desorbed. For example, H atoms are desorbed by using P atoms for ion implantation. However, atoms used for ion implantation may be atoms of the same type as atoms to be desorbed. H atoms may be desorbed from the semiconductor layer 71, for example, by implanting H ions into the semiconductor layer 71 of the second embodiment.

When this is applied to the semiconductor layer 37 of the first embodiment, if H ions are implanted into the semiconductor layer 37, despite intending to decrease the concentration of H atoms in the semiconductor layer 37, the concentration of H atoms in the semiconductor layer 37 may increase. However, one implanted H ion generally disconnect a plurality of Si—H bonds. Therefore, the number of H atoms desorbed from the semiconductor layer 71 is greater than the number of H ions implanted into the semiconductor layer 71. It is thereby possible to decrease concentration of H atoms in the semiconductor layer 37.

Since H ions are light, use of H ions for ion implantation has an advantage that H ions can be more easily implanted up to a deep position. For example, when ions are implanted into any one of stacked films 26, 26′, 53 and 53′, it is preferable to use H ions. H ions in this case may be normal ¹H (light hydrogen) ions or ²H (deuterium: D) ions.

To make it easier for H atoms in the semiconductor layer 71 to escape from the semiconductor layer 71, concave portions such as holes or trenches may be formed in the semiconductor layer 71 before performing annealing for desorption of H atoms. The same is also applicable to layers other than the semiconductor layer 71.

When H atoms are desorbed from a thick film such as the stacked film 26, 26′, 53 or 53′, the thick film may be divided into a plurality of portions. In this case, a step of forming portion of the thick film, a step of implanting ions into the portion, and a step of annealing the portion may be repeated in order. In this case, since the thickness of the portion is smaller than the thickness of the whole thick film, it is possible to easily perform ion implantation.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

1. A semiconductor device comprising:
a stacked film including a plurality of electrode layers and a plurality of insulating layers alternately stacked in a first direction;
a columnar portion including a charge storage layer and a first semiconductor layer extending through the stacked film in the first direction, the first semiconductor layer including an impurity element; and
a second semiconductor layer provided on the stacked film and the columnar portion, the second semiconductor layer including the impurity element and having a concentration gradient of the impurity element in the first direction,
wherein the second semiconductor layer includes:
a first upper face provided in the first direction of the stacked film; and
a second upper face provided in the first direction of the columnar portion, and higher than the first upper face.

2. The device of claim 1, wherein the impurity element is phosphorus.

3. The device of claim 1, wherein an atomic concentration of the impurity element in the first semiconductor layer is 1×10¹⁹ cm⁻³ or more at a position where a depth from an upper end of the first semiconductor layer is 200 nm.

4. The device of claim 1, wherein at least the most upper insulating layer among the plurality of insulating layers includes the impurity element.

5. The device of claim 1, further comprising:
a first substrate;
a first pad provided above the first substrate; and
a second pad provided on the first pad,
wherein the first semiconductor layer is provided at a position higher than a position of the second pad, and electrically connected to the second pad.
